(19) United States
(12) Patent Application Publication
(10) Pub. No.: US 2014/0043901 A1
(43) Pub. Date: Feb. 13, 2014

(54) NONVOLATILE MEMORY DEVICE AND OPERATING METHOD WITH VARIABLE MEMORY CELL STATE DEFINITIONS

(71) Applicant: DONGHUN KWAK, Hwaseong-si (KR)

(72) Inventor: DONGHUN KWAK, Hwaseong-si (KR)

(21) Appl. No.: 13/727,757

(22) Filed: Dec. 27, 2012

(30) Foreign Application Priority Data
Aug. 10, 2012 (KR) 10-2012-0087834

(51) Int. Cl. G11C 16/14; G11C 16/10; G11C 16/06

(52) U.S. Cl. CPC G11C 16/14; G11C 16/06; G11C 16/10
USPC 365/185.03; 365/185.29; 365/185.24; 365/185.22

(57) ABSTRACT

A method operating a nonvolatile memory device includes successively programming a memory cell without physically erasing the memory cell. Each successive programming of the memory cell uses a different erase state region to indicate an erase state for the memory cell.

### CROSS-REFERENCE TO RELATED APPLICATIONS

This U.S. non-provisional patent application claims priority under 35 U.S.C. §119 to Korean Patent Application No. 10-2012-0087834 filed on Aug. 10, 2012, the subject matter of which is hereby incorporated by reference.

### BACKGROUND

The inventive concept relates to semiconductor memory devices and methods programming same. More particularly, the inventive concept relates to semiconductor memory devices incorporating nonvolatile memory cells and programming methods for same. In certain embodiments, the inventive concept relates to semiconductor memory devices having three-dimensional (3D) memory cell arrays of nonvolatile memory cells and programming methods for same.

Semiconductor memory devices may be generally classified as volatile or nonvolatile according to their operative nature. Volatile memory devices lose stored data in the absence of applied power, while nonvolatile memory devices are able to retain stored data even when power is no longer applied.

There are different kinds of nonvolatile memory devices, including for example, the mask read-only memory (MROM), programmable read-only memory (PROM), erasable programmable read-only memory (EPROM), and electrically erasable programmable read-only memory (EEPROM).

Flash memory is a particular type of EEPROM that has been adopted for use in a great variety of digital systems, such as computers, cellular phones, PDAs, digital cameras, camcorders, voice recorders, MP3 players, handheld PCs, games, facsimiles, scanners, printers, and the like. One factor recommending the wide spread use of flash memory in contemporary electronic devices is its high data density. Data density may be understood as the number of digital data bits capable of being stored per unit area occupied by a memory device, or memory system.

Recent attempts to further increase the data density of nonvolatile memory devices such as flash memory devices, have resulted in the development and use of so-called multi-bit memory cells (MLC) along with related programming techniques. The term “multi-level memory cell(s)” or “MLC” has been used to generally denote a class of nonvolatile memory cells capable of storing (and specifically intended to store) more than one bit of binary data. In contrast, “single-level memory cells” or “SLC” are designed and specifically operated to store only a single bit of binary data (e.g., a “1” or “0”). In certain applications, a distinction between MLC and SLC may have more to do with the particular programming, erase, and/or read techniques applied to the memory cells rather than the physical structure of the memory cells. Nonetheless, the provision of nonvolatile memory cell arrays with MLC rather than SLC has resulted in dramatic increases in overall data density.

Other recent attempts to further increase the data density of nonvolatile memory devices such as flash memory devices, have resulted in the development of the so-called three-dimension (3D) memory cell array. Historically, memory cell arrays were implemented as planer (2D) arrangements of memory cells, word lines and bits lines. However, 3D memory cell arrays essentially stack a plurality of 2D memory cell arrays to increase data density of the resulting structure.

It is conventionally understood that certain types of nonvolatile memory cells are subject to operational stress or fatigue when programmed and/or erased over a prescribed number of cycles. Such “worn” nonvolatile memory cells are not capable of reliably storing and providing data.

### SUMMARY

In one embodiment, the inventive concept provides a programming method for a nonvolatile memory including a main area and a buffer area, the method comprising; programming first data in a nonvolatile memory cell of the buffer area using a single-bit programming operation in accordance with one of an erase state and a program state, invalidating the first data stored in the nonvolatile memory cell, and thereafter redefining the erase state.

In another embodiment, the inventive concept provides an operating method for a nonvolatile memory device, the method comprising; programming first data in a nonvolatile memory cell using an Nth erase state among a group of 1^{st} through Mth erase states, and an Nth program state among a group of 1^{st} through Mth program states, where “N” is an integer ranging from 1 to M, determining that an erase re-definition event has occurred for the nonvolatile memory cell, redefining the Nth erase state to an (Nth+1) erase state, redefining the Nth program state to an (Nth+1) program state, and after programming the first data in the nonvolatile memory cell, programming second data in the nonvolatile memory cell in accordance with the (Nth+1) erase state and the (Nth+1) program state before physically erasing the nonvolatile memory cell.

In another embodiment, the inventive concept provides an operating method for a nonvolatile memory device comprising; successively programming a nonvolatile memory cell without physically erasing the memory cell, wherein each successive programming of the memory cell uses a correspondingly expanded erase state region to indicate an erase state for the memory cell.

In another embodiment, the inventive concept provides a nonvolatile memory, comprising; a first memory including an array of nonvolatile memory cells arranged according to a plurality of word lines and a plurality of bit lines, and a second memory storing state information for the nonvolatile memory cells of the first memory, the state information defining a first erase state having a first erase state region, and a second erase state having a second erase state region broader than the first erase state region.

In another embodiment, the inventive concept provides a nonvolatile memory, comprising; control logic responsive to state information that controls successive execution of a first programming operation and a second programming operation, a memory cell array of nonvolatile memory cells, and a voltage generator operating under control of the control logic that during the first programming operation provides a first programming voltage to program a selected nonvolatile memory cell in accordance with a first erase state, and during the second programming operation provides a second programming voltage higher than the first programming voltage to program the selected nonvolatile memory cell in accordance with a second erase state different from the first erase state.

In another embodiment, the inventive concept provides a memory system, comprising; a nonvolatile memory device and a controller configured to control operation of the nonvolatile memory device according to stored state information, wherein the state information defines for each nonvolatile memory cell of the nonvolatile memory device a first erase state having a first erase state region and a second erase state having a second erase state region broader than the first erase state region, the controller being further configured to control execution of a first programming operation directed to a selected nonvolatile memory cell using the first erase state, and execution of a second programming operation directed to the nonvolatile memory cell using the second erase state, the second programming operation being successively executed after the first programming operation before physical erasure of the selected nonvolatile memory cell.

### BRIEF DESCRIPTION OF THE FIGURES

Certain embodiments of the inventive concept are described hereafter with reference to the accompanying drawings.

FIG. 1 is a block diagram illustrating an erase operation performed in a buffer area of a nonvolatile memory device.

FIG. 2 is a block diagram illustrating a nonvolatile memory device in accordance with some embodiments of the inventive concept.

FIG. 3 is a perspective diagram illustrating one possible example of a three-dimensional (3D) memory cell array that may be incorporated in the nonvolatile memory device of FIG. 2.

FIG. 4 is a perspective cross sectional view further illustrating one memory block of the 3D memory cell array of FIG. 3.

FIG. 5 is an equivalent circuit diagram for the memory block of FIG. 4.

FIG. 6 is a flow chart summarizing an operating method for a nonvolatile memory device according to an embodiment of the inventive concept.

FIG. 7 is a flow chart summarizing an operating method for a nonvolatile memory device according to another embodiment of the inventive concept.

FIG. 8, inclusive of FIGS. 8A, 8B and 8C, is a conceptual drawing further illustrating certain control methods in accordance with embodiments of the inventive concept.

FIG. 9 is a flow chart summarizing an operating method for a nonvolatile memory device according to yet another embodiment of the inventive concept.

FIG. 10 is a flow chart further illustrating one example of the step of expanding the erase state region in the flow chart of FIG. 9.

FIG. 11 is a flow chart further illustrating one example of the step of erasing a memory cell in the flow chart of FIG. 9.

FIG. 12 is a conceptual drawing further illustrating certain methods of redefining an erase state region according to embodiments of the inventive concept.

FIG. 13 is a voltage diagram illustrating possible program voltage(s) and verification voltage(s) that may be used to program a nonvolatile memory cell in certain embodiments of the inventive concept.

FIG. 14 is a conceptual diagram further illustrating certain program methods according to embodiments of the inventive concept.

FIG. 15 14 is a conceptual diagram further illustrating certain program methods according to embodiments of the inventive concept.

FIG. 16 is a block diagram illustrating a nonvolatile memory device in accordance with an embodiment of the inventive concept.

FIG. 17 is a block diagram illustrating a nonvolatile memory device in accordance with another embodiment of the inventive concept.

FIG. 18 is a block diagram illustrating a memory system in accordance with an embodiment of the inventive concept.

FIG. 19 is a block diagram illustrating a memory system in accordance with certain embodiments of the inventive concept.

FIG. 20 is a block diagram illustrating a solid state drive (SSD) in accordance with certain embodiments of the inventive concept.

FIG. 21 is a block diagram illustrating a memory card in accordance with certain embodiments of the inventive concept.

FIG. 22 is a block diagram illustrating a computational system in accordance with certain embodiments of the inventive concept.

### DETAILED DESCRIPTION OF THE EMBODIMENTS

Certain embodiments of the inventive concept will now be described in some additional detail with reference to the accompanying drawings. The inventive concept may, however, be embodied in many different forms, and should not be construed as being limited to only the illustrated embodiments. Rather, these embodiments are provided as examples so that this disclosure will be thorough and complete, and will fully convey the concept of the inventive concept to those skilled in the art. Accordingly, conventional understood processes, elements, and techniques may not be described in detail with respect to some of the illustrated embodiments. Unless otherwise noted, like reference numbers and labels are used to denote like or similar elements throughout the drawings and written description.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

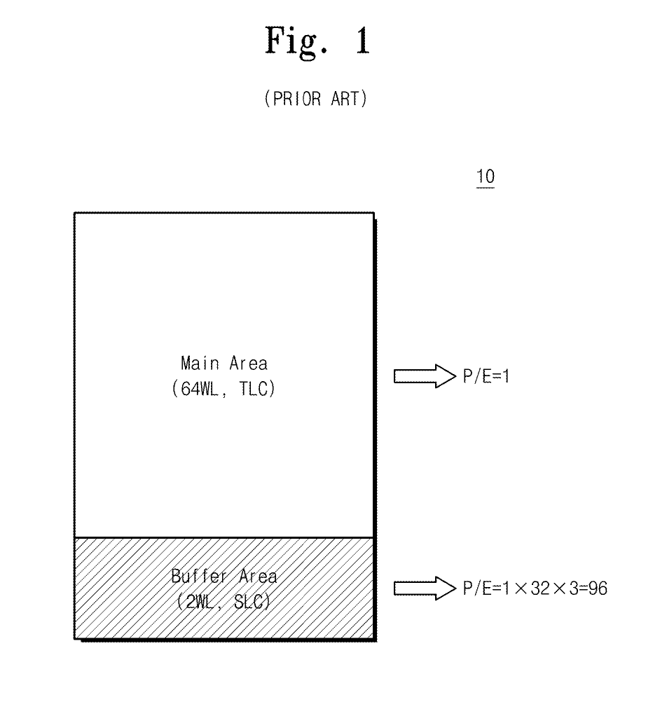

FIG. 1 is a block diagram illustrating one example of an erase operation being executed in a conventional nonvolatile memory device 10 including designated “buffer” and “main” areas. The buffer area may be used to receive, aggregate and temporarily store incoming data, whereas the main area may be used to store data provided from the buffer area. As is typical, the buffer area is significantly smaller than the main area.

For example, the memory cell array constituent to the nonvolatile memory device 10 is assumed to include 64 word lines (WL) associated with the main data area and only 2 WL associated with the buffer area. It is further assumed that the nonvolatile memory cells of the main area are operated (e.g., programmed, read and/or erased) as 3-bit MLC (or “TLC”), while the nonvolatile memory cells of the buffer area are operated as a single bit SLC. Finally, it is assumed that each nonvolatile memory cell in the nonvolatile memory device 10 is a flash memory cell that must be erased before being re-programmed. That is, following an initial programming of each flash memory cell, each successive programming of the flash memory cell requires a prior erasing of the flash memory cell. Under these conventional assumptions, the single erasure of a 3-bit flash MLC in the main area requires the commensurate erasures of corresponding SLC in the buffer area up to 96 times. That is, the erasure of each bit of data stored in a 3-bit MLC of the main area requires up to 32 erasures of corresponding SLC in the buffer area.

This outcome illustrates a real potential problem with conventional nonvolatile memory devices including a buffer area of relatively high-speed buffer SLC passing program data to a main area of relatively low-speed MLC. Those skilled in the art will recognize that very frequent erasure of the memory cells in a buffer area, for example, will rapidly deteriorate the performance of the nonvolatile memory device. This may be particularly true for memory cells associated with a vertical NAND flash (VNAND) memory devices that are characterized by relatively long erase time(s).

In view of foregoing and other conventional memory system arrangements and operational parameters that necessarily result in dramatic wear of nonvolatile memory cells, embodiments of the inventive concept provide operating methods and memory systems that require less frequent physical erasing (or fewer physical erasures) of constituent nonvolatile memory cells. The terms “physical erasing” or “physical erasure” are introduced here to better distinguish conventional approaches to the re-programming of nonvolatile memory cells. That is, those skilled in the art understand that a previously programmed nonvolatile memory cell (i.e., a nonvolatile memory cell having been programmed to a threshold voltage state other than an erase state) must first be “physically erased” by application of certain control voltages that restore the threshold voltage of the nonvolatile memory cell to the erase state. Using an example of flash memory cells, certain control voltages, as variously defined by level and duration in the art, may be applied to substantially remove (or discharge) electrical charge from a gate structure of the flash memory cell, thereby restoring the threshold voltage of the flash memory cell to an erase state.

In contrast, certain embodiments of the inventive concept provide what may be understood as one or more “logical erasure(s)” to a successively programmed nonvolatile memory cell before having to physical erase the nonvolatile memory cell at some point in its successive programming. Such logical erasure is accomplished by essentially redefining various states used to program, verify and/or read the nonvolatile memory cell. For example 1 to M valid erase states may be defined for a nonvolatile memory cell. During a first programming of the nonvolatile memory cell, a 1^{st} erase state definition indicated by a corresponding 1st erase state region of a possible threshold voltage distribution for the nonvolatile memory cell may be used. Then, during a second successive programming of the nonvolatile memory cell, a 2^{nd} erase state definition indicated by a corresponding 2^{nd} erase state region of the threshold voltage distribution for the nonvolatile memory cell may be used, different from the 1^{st} erase state region. By using a different definition for the erase state (e.g., a state corresponding to a data value of ‘1’ in a SLC) of the nonvolatile memory cell, the control logic of the memory system avoids the conventional requirement to first physically erase the nonvolatile memory cell before the second programming operation. This concept will be expanded upon hereafter in some additional detail.

Returning to the example described above in relation to FIG. 1, the buffer area memory cells used to pass program data to main area memory cells need not be physically erased with such frequency, if a number of conventionally required physical erasures could be substituted by logical erasures. The erase and program states for the memory cells of a buffer memory are readily susceptible to definition during successive programming operations, since the single bit data stored in the SLC of the buffer area may be invalidated once the data has been successfully passed to the memory cells of the main area. The term “invalidated” as used in this context refers to any number of events that essentially allows stored data to be deemed redundant, out-of-date, no longer needed, or no longer accurate. Such events include passing of data from a buffer, copying data to a new location, consolidation or aggregation of data (e.g., garbage collection), error detection, etc.

In any event, once the “migrating” data or “errant” data is no longer deemed valid, the erase state and/or program state(s) for the buffer area memory cell may be redefined to logically erase the buffer area memory cell. Several possible approaches to erase and program state redefinition will be described hereafter in some additional detail.

It should be noted that the scope of the inventive concept is not limited to only memory devices, memory systems, and programing methods using a buffer memory. Nor is the scope of the inventive concept limited to flash memory cells and related systems and methods, despite the fact that several of the enabling embodiments described hereafter assume the use of flash memory cells.

Rather, the scope of the inventive concept covers all nonvolatile memory devices capable of redefining an erase state and/or program state(s) to thereby enable omission of a physical erase operation for constituent memory cells between at least two successive program operations.

For example, the same technical effect may be obtained in certain embodiments of the inventive concept as applied to memory cells storing meta data. As will be appreciated by those skilled in the art, meta data is frequently updated. Rather than physically erasing memory cells in response to each a meta data update request, the erase and/or program states of the nonvolatile memory cells used to store the meta data may be redefined to effect logical erasures intermediate to successive physical erasures. In this manner, the number of (physical) erase operations applied to the nonvolatile memory cells storing meta data may be dramatically reduced.

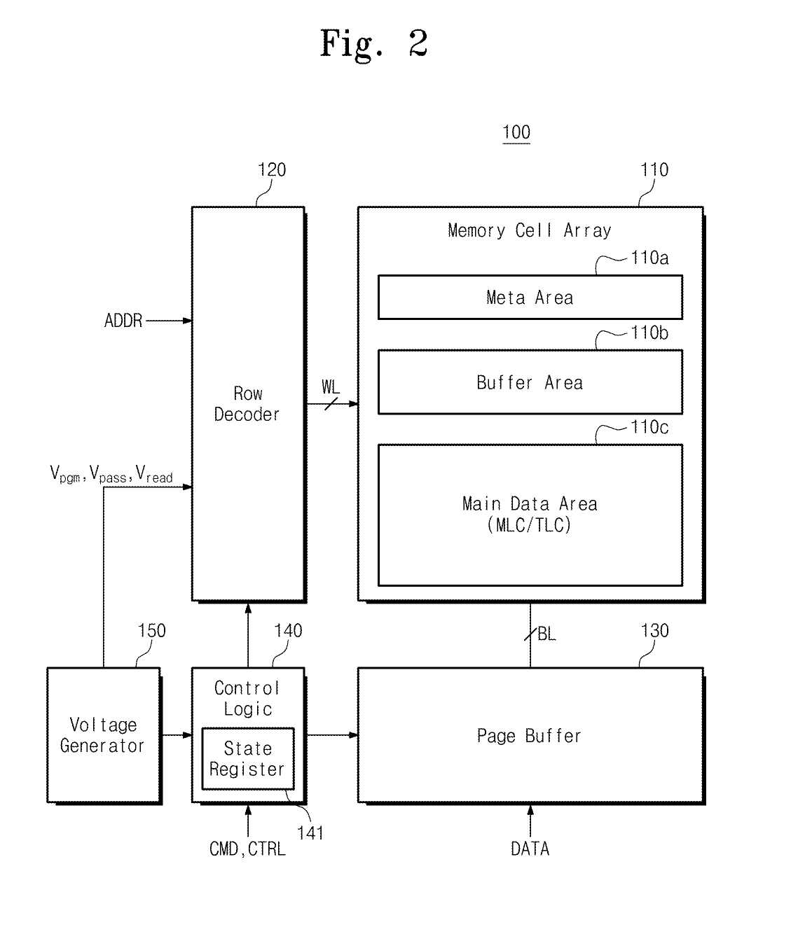

FIG. 2 is a block diagram illustrating a nonvolatile memory device in accordance with certain embodiments of the inventive concept. Referring to FIG. 2, the nonvolatile memory device 100 generally comprises in relevant part; a memory cell array 110, a row decoder 120, a page buffer 130, control logic 140 and a voltage generator 150.

The memory cell array 110 includes a plurality of cell strings disposed on a substrate in row and column directions. Each cell string includes a plurality of memory cells stacked in a direction perpendicular to the substrate. That is, memory cells are provided on the substrate along a row direction and a column direction and stacked in a direction perpendicular to the substrate to form a three dimensional structure. The memory cell array 110 includes a plurality of nonvolatile memory cells that is each capable of storing one or more bits per memory cell.

For example, the memory cell array 110 of FIG. 2 may include a main data area 110c used to store data received by the nonvolatile memory device 100, a buffer area 110b used to temporarily store the data to be stored in the main data area 110c, and a meta area 110a used to store data related to meta information. The memory cells of the main data area 110c may be used (e.g., programmed, read and erased) as MLC, whereas the memory cells of the buffer area 110b and the memory cells of the meta area 110a may be used as SLC.

The row decoder 120 is connected to the memory cell array 110 through a plurality of word lines (WL), and may be configured to operate in response to control signals provided by the control logic 140 and in response to an externally provided address (ADDR). That is, the row decoder 120 may be configured as a row address decoder responsive to the received address, wherein the row decoder 120 selects one or more word line(s) among the plurality of word lines indicated by a decoded row address portion of the received address.

Within this configuration, the row decoder 120 is able to supply control voltages provide by the voltage generator 150 to a selected word line and to unselected word lines in response to the decoded row address and the control signals received from the control logic 140. For example, the row decoder 120 may receive and selectively provide a pass voltage (Vpass), a program voltage (Vpgm), a read voltage (Vread), etc. to the plurality of word lines.

The page buffer 130 is connected to the memory cell array 110 through a plurality of bit lines BL, and operates in response to control signals provided by the control logic 140 to selects one or more bit line(s) from among the plurality of bit lines. In certain embodiments, the page buffer 130 may include a plurality of individual page buffer circuits connected to one or more bit line(s) according to a defined architecture. Each page buffer may include a data latch and a rearrange latch.

Under the control of the control logic 140, the row decoder 120 and the page buffer 130 cooperate to execute program and read operations. That is, by selective control of the word lines by the row decoder 120 and selective control of the bit lines by the page buffer 130, one or more memory cells may be selected in the memory cell array 110 during the execution of a program operation or a read operation. During a program operation, a verification read operation may be performed, as is understood by those skilled in the art. The page buffer 130 is further configured to provide read data as the result of a read operation or a verification read operation, and receive program data (DATA) during a program operation.

The program data received by the page buffer 130 will be written to the memory cell array 110. That is, the page buffer 130 may be used to program data to the buffer area 110b and subsequently transfer the temporarily stored program data to the main area 110c and/or the meta area 110a. Alternately, program data stored in the page buffer 130 may be written directly to the main area 110c or meta area 110a. Certain conventionally understood operations may be used to “housekeep” the various areas of the memory cell array 110 and include (e.g.,) garbage collection operations, copy-back operations, etc.

The voltage generator 150 may be used to generate various voltages under the control of the control logic 140. For example, the voltage generator 150 may generate the pass voltage (Vpass), program voltage (Vpgm), the read voltage (Vread) as well as a verification voltage (Vvfy). Of note, certain embodiments of the inventive concept require that one or more of these control voltages be provided at one of a multiplicity of different levels during program, read and erase operations, depending on the current definition of the erase state definition and/or program state(s).

The control logic 140 is configured to control an overall operation of the nonvolatile memory device 100 (e.g., program, read and erase operations). The control logic 140 may operate in response to certain externally provided control signals (CTRL) and/or commands (CMD). The control logic 140 may receive the results of a verification read operation from the page buffer 130 in order to determine which memory cells are program pass or program fail, for example.

Additionally, the control logic 140 may be used to determine nature or validity of data stored in a nonvolatile memory cell of the memory cell array 110 according to current definitions of the erase state and/or program state(s). For example, the control logic 140 may be used, after a data invalidating event (e.g., a data transfer from a buffer memory or a meta data update request), to redefine the erase state and/or program state of a buffer area memory cell, such that the buffer area memory cell need not be physically erased before again being programmed.

In certain embodiments of the inventive concept, the function of “redefining” an erase state or program state will involve the control logic 140 changing relevant state information stored in a state register 141. Such state information may subsequently be used to define the level of control voltages used during successive program operations, or used to interpret stored data during successive read operations. Accordingly, in certain embodiments of the inventive concept, one or more table(s) of state information may be referenced and/or one or more entries in a state information register may be changed by the control logic 140 in order to effect the redefinition of the erase state and/or a program state. Additionally, the state information—as interpreted by the control logic 140—may indicate that a physical erase operation is required for a particular nonvolatile memory cell.

For example, in certain embodiments of the inventive concept, the control logic 140 may expand the range of a threshold voltage distribution indicating the erase state. Thus, an initially defined first erase threshold voltage distribution indicating the erase state during a first programming operation may be expanded to broader, second erase state threshold voltage distribution indicating the erase state during a second programming operation following the first programming operation. In effect, the erase state region of the overall threshold voltage distribution range for the nonvolatile memory cell is increased in order to provide a logical erase operation that avoids the necessity of performing a physical erase operation.

Of course the overall threshold voltage distribution range for a nonvolatile memory cells (i.e., the range from a minimum threshold voltage to a maximum threshold voltage for the nonvolatile memory cell) established a practical limit on the number of times the erase state region may be expanded. Once a maximum erase state region (or maximum erase state threshold voltage distribution) is reached for a nonvolatile memory cell, the next re-use (e.g., a next programming operation) will require a prior physical erasing of the nonvolatile memory cell. The physical erasing has the effect of returning (or re-initializing) the definition of the erase state back to an initial (e.g., minimally broad) erase threshold voltage distribution. The state information may also be used to define (or re-define) control voltages associated with successive programming operations and read operations having redefined erase and/or program states.

State information may be managed by the control logic 140 and may be stored in the state register 141 of the control logic 140 and/or in the meta area 110a of the memory cell array 110. State information, including at least one of erase state information, program state information, and control voltage information, may be managed on a page-by-page basis and/or a memory block-by-memory block basis.

Memory systems, like memory system 100 of FIG. 2, according to embodiments of the inventive concept, are accordingly able to program one or more nonvolatile memory cells in a memory cell array without a one-for-one requirement to perform an erase operation. As a result, the frequency of erase operations applied to the nonvolatile memory cell may be reduced, thereby markedly postponing deterioration of the nonvolatile memory cells and avoiding reduction in operating speed due to the conventionally applied multiplicity of erase operations.

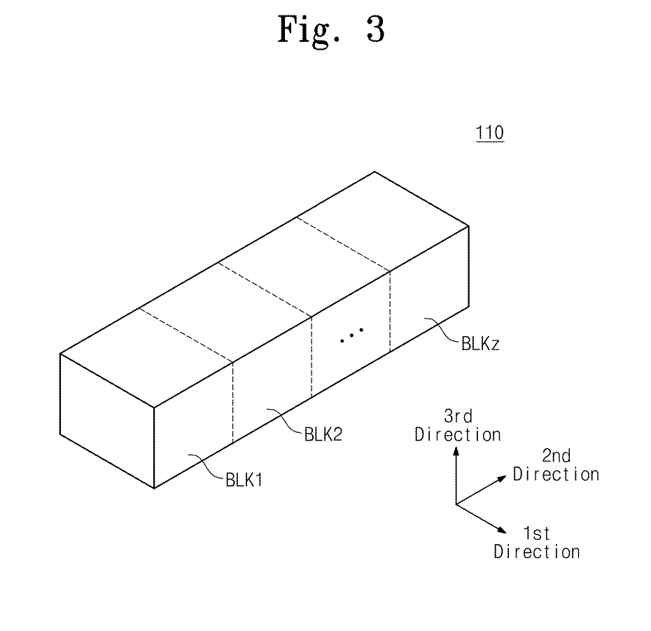

FIG. 3 is a perspective diagram illustrating one possible example of the memory cell array 110 of FIG. 2. Referring to FIGS. 2 and 3, the memory cell array 110 includes a plurality of memory blocks BLK1˜BLKz. Each memory block BLK has a three dimensional structure (or vertical structure). Each memory block BLK may include structures extending in first through third directions. Each memory block BLK may include a plurality of strings (not shown) extending in the second direction. The plurality of strings may be separated from one another along the first and third directions.

Cell strings of one memory block are connected to a plurality of bit lines BL, a plurality of string select lines SSL, a plurality of word lines WL, one or a plurality of ground select lines GSL and a common source line (not shown). Cell strings of the plurality of memory blocks BLK1˜BLKz can share the plurality of bit lines BL. The plurality of bit lines BL extends along the second direction to be shared in the plurality of memory blocks BLK1˜BLKz.

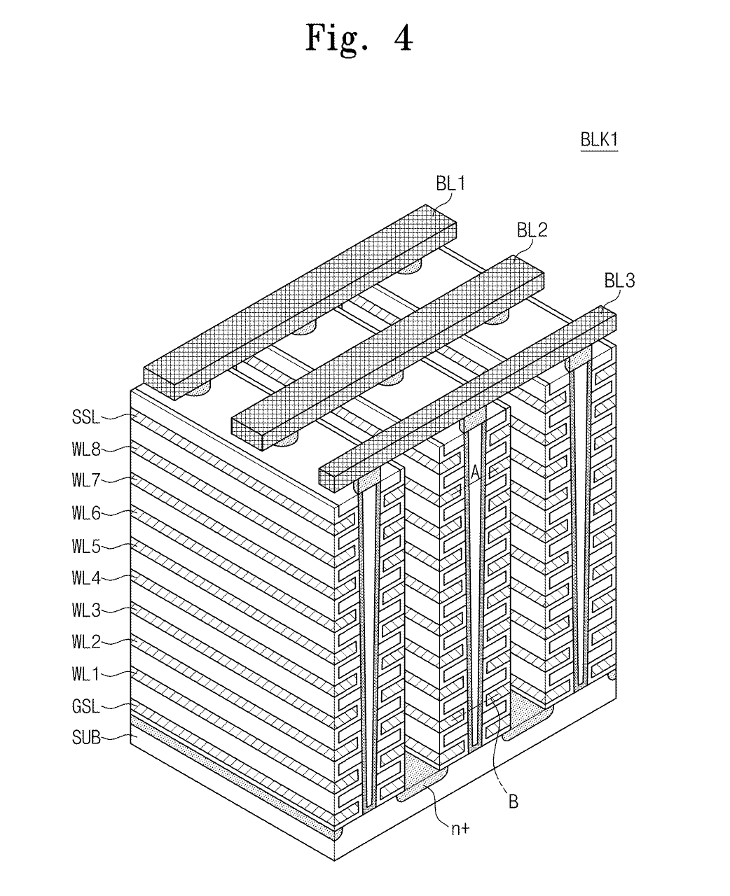

The memory blocks BLK1˜BLKz may be selected by the row decoder 120. The row decoder 120 can select a memory block corresponding to the received address ADDR among the memory blocks BLK1˜BLKz. Program, read and erase operations are performed in the selected memory block. The memory blocks BLK1˜BLKz will be described in more detail with reference to FIG. 4.

FIG. 4 is a perspective cross sectional view further illustrating one memory block of the memory cell array 110 of FIG. 3. Referring to FIG. 4, a first memory block (BLK1) is formed along a direction perpendicular to a substrate (SUB). An n+ doping region is formed in the substrate. A gate electrode layer and an insulation layer are alternately deposited on the substrate.

An information storage layer is formed between the gate electrode layer and the insulation layer. The information storage layer in the illustrated example includes a tunnel insulation layer, a charge storage layer and a blocking insulation layer.

After patterning the gate electrode layer and the insulation layer in a vertical direction, a V-shaped pillar is formed. The pillar penetrates the gate electrode layer and the insulation layer to be connected to the substrate. The inside of the pillar is a filing dielectric pattern and may be constituted by an insulation material such as silicon oxide. The outside of the pillar is a vertical active pattern and may be constituted by a channel semiconductor.

Referring to the illustrated example of FIG. 4, the gate electrode layer of the memory block BLK1 is connected to a ground select line GSL, a plurality of word lines WL1˜WL8 and a string select line SSL. The pillar of the memory block BLK1 may be connected to a plurality of bit lines BL1˜BL3. In FIG. 4, one memory block BLK1 is illustrated to have two select lines GSL and SSL, eight word lines WL1˜WL8 and three bit lines BL1˜BL3 but the inventive concept is not limited thereto.

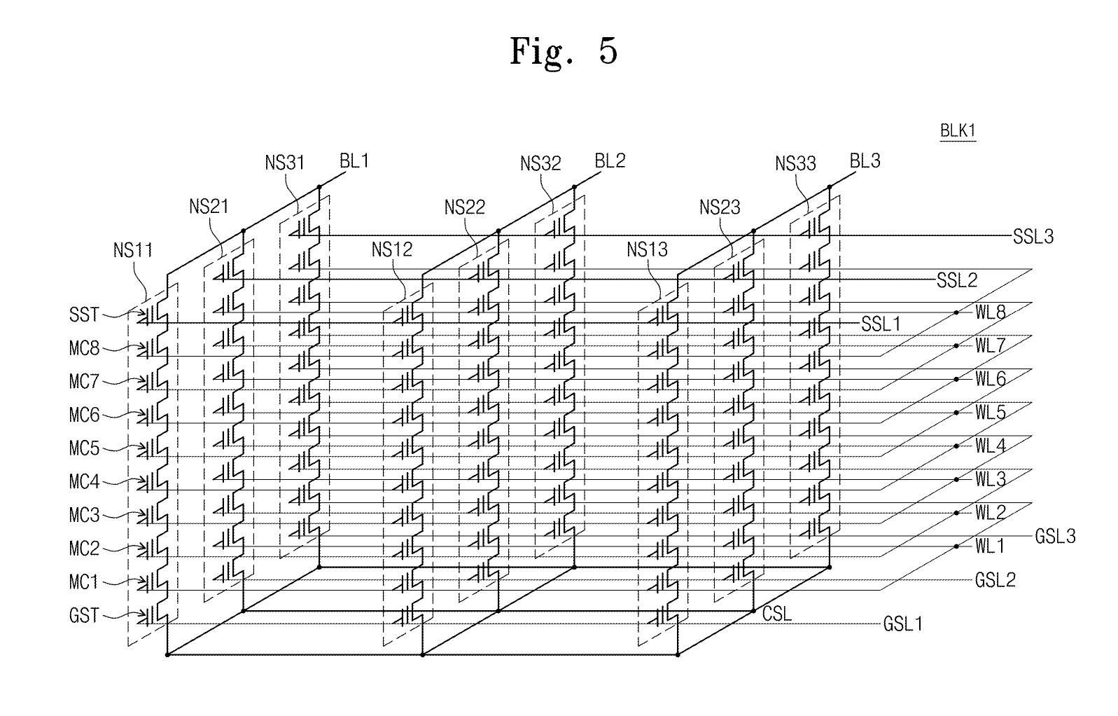

FIG. 5 is an equivalent circuit diagram of the first memory block BLK1 illustrated in FIG. 4. Referring to FIG. 5, NAND strings NS11˜NS33 are connected between the bit lines BL1˜BL3 and the common source line CSL. Each NAND string (for example, NS11) includes a string select transistor SST, a plurality of memory cells MC1˜MC8 and a ground select transistor GST.

The string select transistor SST is connected to string select lines SSL˜SSL3. The plurality of memory cells MC1˜MC8 is connected to the word lines WL1˜WL8 respectively. The ground select transistor GST is connected to a ground select line GSL. The string select transistor SST is connected to a bit line BL and the ground select transistor GST is connected to a common source line CSL.

Referring to FIG. 5, a word line (e.g., WL1) disposed at a same “height” above the substrate is connected in common and the string select lines SSL1˜SSL3 are separated from one another. When programming a set of memory cells (hereinafter, “a page”) which is connected to the first word line WL1 and belongs to the NAND strings NS11, NS12 and NS13, the first word line WL1 and the first string select line SSL1 are selected.

Regardless of whether the memory cell array of a nonvolatile memory device consistent with an embodiment of the inventive concept is a 2D or a 3D memory cell array, the constituent nonvolatile memory cells may be successively programmed according to an operating method that reduces the number of erase operation applied to the nonvolatile memory cells.

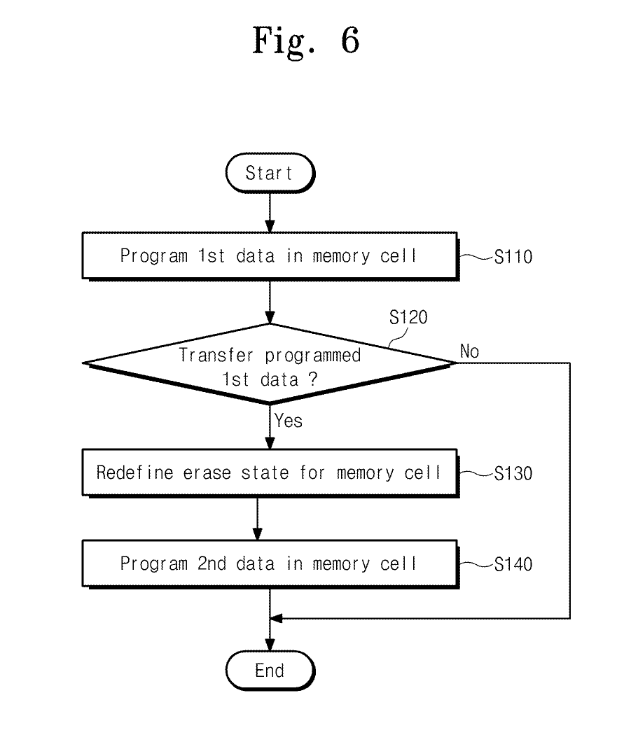

For example, FIG. 6 is a flow chart summarizing an operating method for a nonvolatile memory device according to an embodiment of the inventive concept. Referring to FIG. 6, the operating method begins in relevant portion when first data is programmed to a first nonvolatile memory cell in a nonvolatile memory device (S110). More particularly, the first programming operation is performed in response to a first program command (or instruction) received by a nonvolatile memory device having a memory cell array including a buffer area and a main area, wherein step S110 programs the first data in a SLC of the buffer area using a first program voltage Vpgm1, and a corresponding first verification voltage Vvfy1.

Then, a determination is made as to whether the first data has been successfully transferred from the first nonvolatile memory cell to a second nonvolatile memory cell in the main area (S120=YES). It is assumed that the second nonvolatile memory cell of the main area is MLC. The determination of a successful transfer of first data from the buffer area to the main area effectively invalidates the data stored in the first nonvolatile memory cell, and is one example of a number of possible “data invalidating events” or a number of possible “state redefinition events”.

Accordingly, upon determining that the first data has been successfully transferred to the second nonvolatile memory cell in the main area—as a state redefinition event for the first nonvolatile memory cell—the operating method redefines at least the erase state used to next store data in the first nonvolatile memory cell (S130). There are a number of ways to redefine the erase state (or a program state). In one approach, a first (or initial) erase state threshold voltage distribution, assuming a single prior programming of the first nonvolatile memory cell, may be expanded to a second erase state threshold voltage distribution broader than and subsuming the first erase state threshold voltage distribution. In certain embodiments of the inventive concept, the second erase state threshold voltage distribution subsumes a first program state threshold voltage distribution resulting from application of the first program voltage Vpgm1. This outcome therefore necessitates the commensurate redefinition of the program state from the first programming state threshold voltage distribution to a higher (outside the second erase state threshold voltage distribution) second program state threshold voltage distribution, such that the first nonvolatile memory cell may be re-programmed during a next successive programming operation.

With the redefinition of the erase state and program state completed for the first (SLC) nonvolatile memory cell of the buffer region, it may be programmed with second data according to the second erase state and the second program state using a second programming voltage Vpgm2, and a corresponding second verification voltage Vvfy2 (S140). Here, the second programming voltage will be of sufficient level to place the threshold voltage of the programmed SLC in the second program state threshold voltage distribution, while the second verification voltage is of sufficient level to discriminate between the second erase state and the second program state.

As part of the erase state and program state redefinition step, for example, state information characterizing the first nonvolatile memory cell may be updated in the state register 141 of the control logic 140 and/or in the meta area 110a of the memory cell array 110.

According to the operating method of FIG. 6, the respective nonvolatile memory cells of the nonvolatile memory device 100 of FIG. 2, for example, may be successively programmed without performing a physically erasing operation. That is, two or more programming operations may be successively applied to a nonvolatile memory cell without an intervening physical erasure. This omission of physical erase operations increases the operating speed of the nonvolatile memory device 100 and reduces memory cell wear thereby postponing memory system performance deterioration.

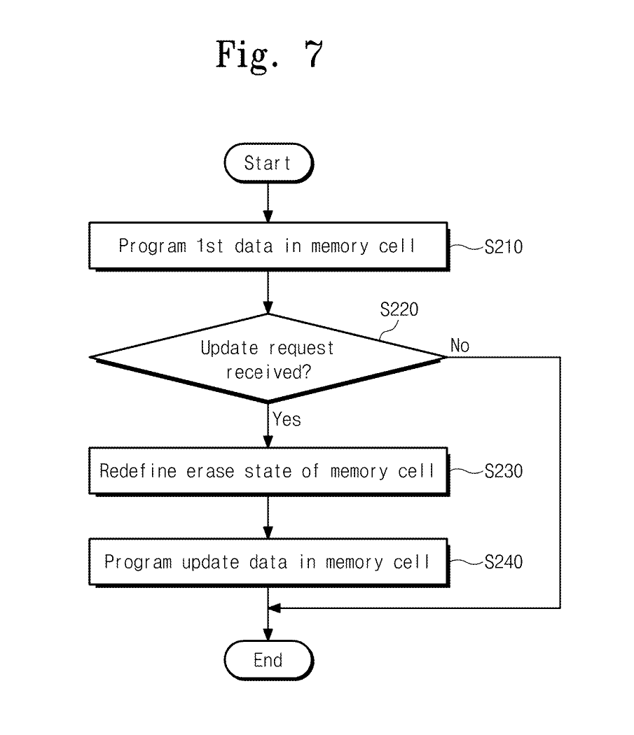

FIG. 7 is a flow chart illustrating an operating method for a nonvolatile memory device according to another embodiment of the inventive concept. Here, it is assumed that a SLC in the meta area 110a of FIG. 2 is being updated.

The nonvolatile memory cell in the meta area 110a is first programmed with data (S210). Then, an update request for the meta data stored in the nonvolatile memory cells is received (S220). This update request is treated as a data invalidating event, and therefore, a state redefinition event. Accordingly, the erase state (and possibly the program state) of the nonvolatile memory cell is redefined (S230). Then, the data stored in the nonvolatile memory cell may be updated with new data in accordance with the redefined erase and/or program state(s) (S240).

The erase state and program state may be redefined as described above, together with corresponding control voltages and state information.

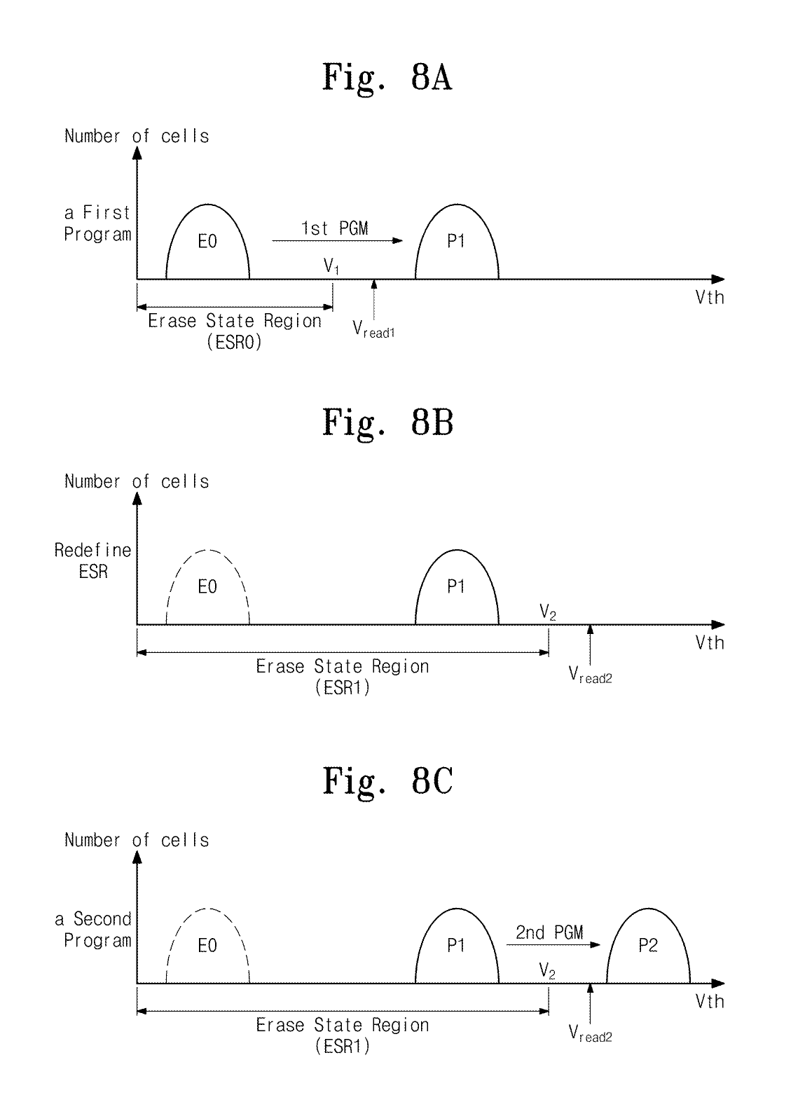

FIG. 8, inclusive of FIGS. 8A, 8B and 8C, is a drawing further illustrating an operating method in accordance with certain embodiments of the inventive concept.

Referring to FIG. 8A, an initial (first) erase state is assumed for a single-level, nonvolatile memory cell (e.g., erase state E0). The first erase state may be distinguished from an initial (first) program state (e.g., program state P1) using a first read voltage Vread1. The first erase state is nominally assumed by the Gaussian distribution curve E0 but is assumed to extend no higher in the overall threshold voltage distribution for the nonvolatile memory cell than a first maximum voltage V1. Hence, a first erase state region (ESR0) within the overall threshold voltage distribution extends up to the first maximum V1.

Upon the occurrence of a state redefinition event (e.g., a data transfer form a buffer memory or a data update in meta memory) and as illustrated in FIG. 8B, the erase state for the nonvolatile memory cell is redefined from the first ESR0 to a second ESR1 extending up to a second maximum voltage V2 that subsumes not only the first erase state region, but also the first program state region P1.

Accordingly, as illustrated in FIG. 8C, it is necessary to redefine the program state for the nonvolatile memory cell, since a threshold voltage falling within the first program state threshold voltage distribution will now be interpreted as falling within the (re-defined second) erase state. Hence, a second program state threshold voltage distribution P2 is defined higher than the first program state threshold voltage distribution P1 and outside of the second erase state region ESR1. Further, a second program voltage Vpgm2 is defined sufficient to place the threshold volateg of the nonvolatile memory cell in the second program state and a second read voltage Vread2 is defined to distinguish between the second erase state and the second program state.

Thus, in a step of redefining an erase state region, the nonvolatile memory device 100 of FIG. 2 may expand the erase state region from a first erase state region ESR1 so that the program state P1 (a first program state) is read as the erase state. That is, the nonvolatile memory device 100 may expand the erase state region from a first erase state region to a second erase state region (ESR0→ESR1) so that the nominal distribution of threshold voltages indicating the first program state P1 fall within the redefined erase state region for he nonvolatile memory cell.

In this case, in order to distinguish between the redefined erase state and a redefined program state for the nonvolatile memory cell, the level of the relevant control voltage (i.e., the read voltage Vread) must be adjusted to exceed the maximum value V2 for the second erase state region ESR1. Since the determined redefined read voltage Vread2 is now higher than the maximum threshold voltage of the first program state P1, in a read voltage using the read voltage Vread2, the memory cell programmed to the first program state P1 will be read as an erase state. In this manner, a logical erase operation is performed for the nonvolatile memory cell without requirement of actually physically erasing the memory cell.

Once the redefinition step illustrated in FIG. 8 is complete, the nonvolatile memory device 100 may be programmed during a second program operation according to (in relation to) the redefined erase and program states.

After the second program operation is complete, the nonvolatile memory device 100 may perform subsequent read operations using the second read voltage Vread2 distinguishing the second erase state region (ESR1) indicating a data value of ‘1’ from the second program state (P2) indicating a data value of ‘0’.

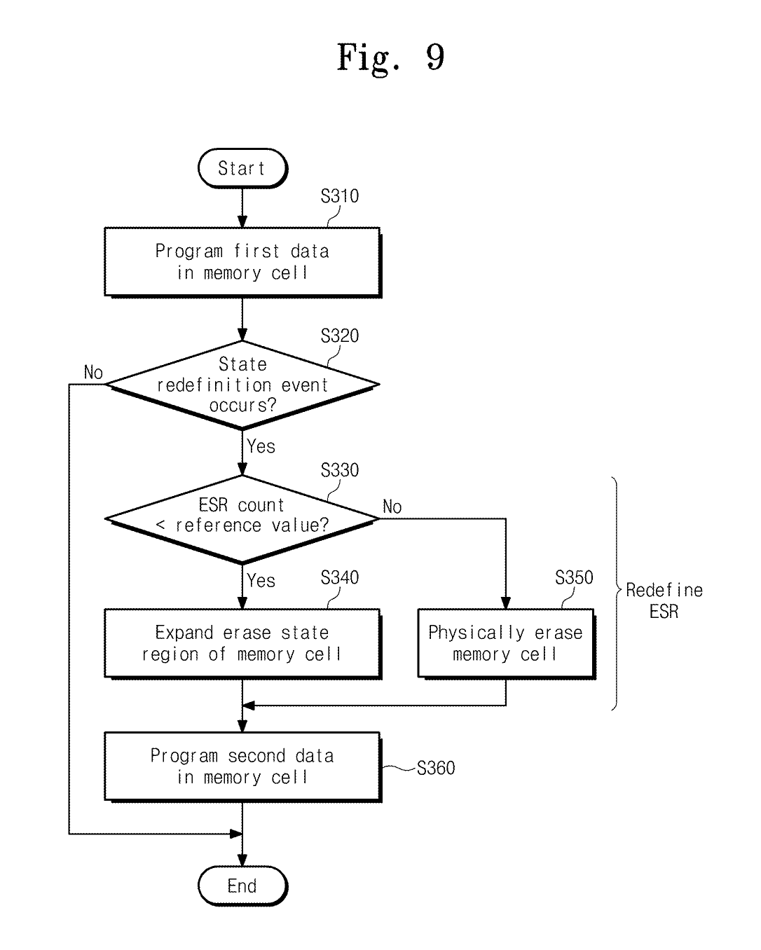

FIG. 9 is a flow chart summarizing an operating method for a nonvolatile memory device according to yet another embodiment of the inventive concept. Referring to FIG. 9, the method again begins with the programming of first data to a nonvolatile memory cell (S310) using a first program voltage and a first program verification voltage. The programming of the first data is performed in accordance with a set of definitions characterizing a first erase state and a first program state for the SLC.

Then, a state redefinition event if detected (S320=YES). As noted above, many different events (i.e., conditions or operations) occurring within the nonvolatile memory device 100 may be detected as a state redefinition event. Some redefinition events invalidate the first data stored in the nonvolatile memory cell. Other redefinition events will ultimately overwrite or update the first data stored in the nonvolatile memory cell.

Upon detecting the redefinition event (S320=YES), the operating method makes a determination as to whether an erase state redefinition (ESR) count value exceeds a prescribed limit or reference value (S330). The state information describing each nonvolatile memory cell in a memory cell array may include a current ESR count value.

During the programming of the first data, for example, the nonvolatile memory cell may have an ESR count value of 0 or 1. If it is assumed that the nonvolatile memory cell 100 has an ESR count value of 0, as indicated by its state information, then the control logic 140 of the nonvolatile memory device 100 will determine that the nonvolatile memory cell should be programmed according to the initial erase state region ESR0 and the initial program state P0. In contrast, if it is assumed that the nonvolatile memory cell has an ESR count value of 1, as indicated by its state information, then the control logic 140 will determine that the nonvolatile memory cell should be programmed according to the second erase state region ESR1 and the second program state P1.

The reference value used to check a current ESR count value (S330) may be correlated with a maximum number of times that the erase and program states of the nonvolatile memory cell may be redefined. For example, there will be upper practical limit(s) on the level of the erase state and/or program state within an overall threshold voltage distribution for a nonvolatile memory cell (a fundamental characteristic of the memory cell). Once the erase state region reaches a maximum breadth following successive expansions counted by the ESR count value, the nonvolatile memory cell will require a physical erasure (i.e., required a re-initialization of the erase state and related program state) in order to be again programmed.

However, so long as ESR count value is less than the reference value (S330=YES), the control logic 140 of the nonvolatile memory device 100 will determine that the erase state region for the nonvolatile memory cell may be expanded (S340).

Once the erase state (and corresponding program state) for the nonvolatile memory cell has either been re-initialized (S350) or expanded (S340), the nonvolatile memory cell may again be programmed with second data (S360).

As before, the requisite control voltages and state information may be defined and updated to reflect the current states for the nonvolatile memory cell.

According to the foregoing operating method for the nonvolatile memory device 100, physical erasures of respective memory cells (or defined groups of memory cells—e.g., a page of memory cells) need only be performed when necessary and only after at least one logical erasure achieved by expanding the erase state region and redefining the program state upward in view of the expanded erase state region.

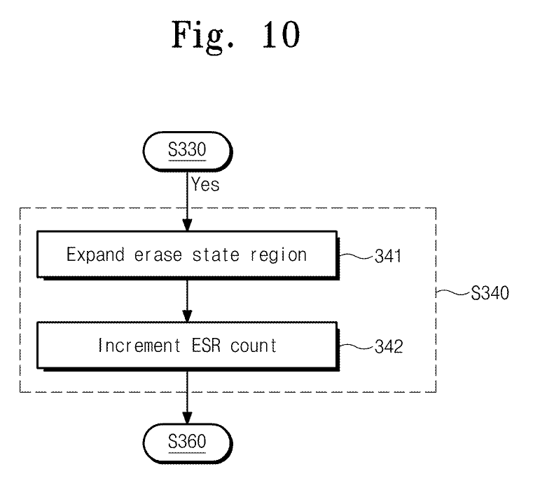

FIG. 10 is a flow chart further illustrating in one example the step of expanding the erase state region (S340) in FIG. 9. Here, the control logic 140 of the nonvolatile memory device 100 expands the erase state region of the nonvolatile memory cell (S341) and then increments the ESR count value contained, for example, in state information for the nonvolatile memory cell (S342). As noted above, the ESR count value may be referenced to generated appropriate control voltages during programming of the nonvolatile memory cell, and may also be referenced to determine if the nonvolatile memory cell requires re-initializing by execution of a physical erase operation.

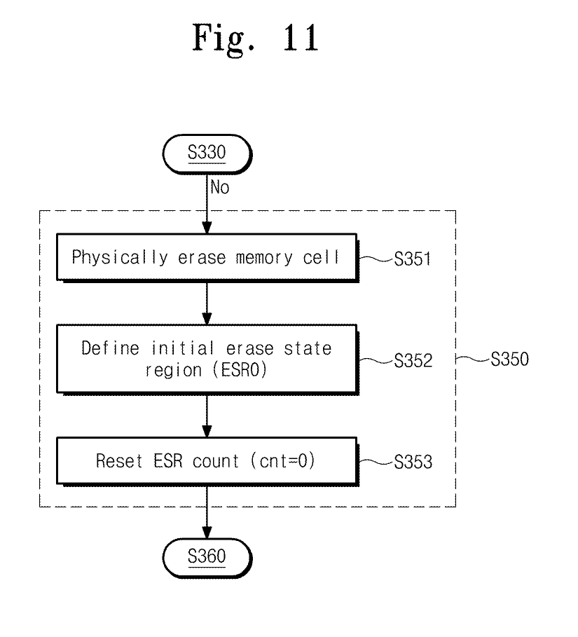

FIG. 11 is a flow chart further illustrating in one example the step of physically erasing the memory cell (S350) in FIG. 9. Here, the nonvolatile memory cell is physically erased using for example a conventional erase operation and control voltage definitions (S351). Then, the state information for the nonvolatile memory cell may be updated to define (or restore the definition of) the initial erase state region ESR0 (S352) and reset the ESR count value to ‘0’ (S353).

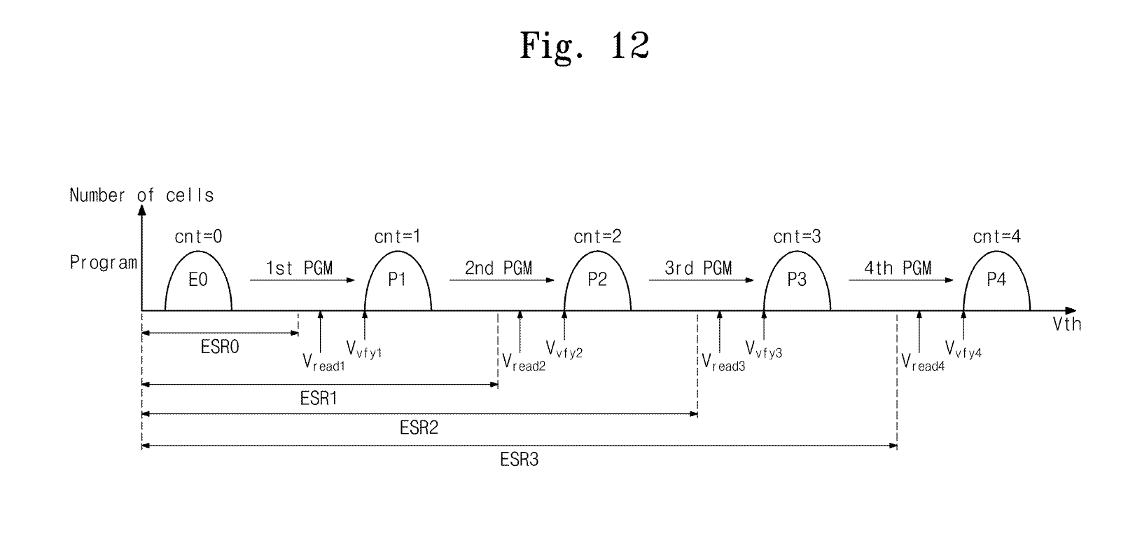

FIG. 12 is a conceptual drawing further illustrating an exemplary operating method that may be used to redefine an erase state region according to an embodiment of the inventive concept. Referring to FIG. 12, the nonvolatile memory cell of interest in now assumed to be operable as a MLC despite being used in a SLC capacity within (e.g.,) a buffer area or meta area of a memory cell array. Hence, consistent with conventional understanding, the nonvolatile memory cell might be programmed according to an erase state E0 and first through fourth program states P1, P2, P3 and P4.

However, consistent with certain embodiments of the inventive concept, at least three (3) of the four (4) “programmable” states (e.g.,) P1, P2, P3 of the MLC may be successive subsumed by an incrementally expanded erase state region (i.e., ESR1, ESR2 and ESR3). Thus, during a first SLC programming operation (1^{st} PGM), an initial erase state region ESR0 and a first program state P0 are used. These states are indicated by an ESR count value of 0. During a second SLC programming operation (2^{nd} PGM), the first erase state region ESR1 and a second program state P2 are used. These states are indicated by an ESR count value of 1. During a third SLC programming operation (3^{rd} PGM), the second erase state region ESR2 and a third program state P3 are used. These states are indicated by an ESR count value of 2. Finally, during a fourth SLC programming operation (4^{th} PGM), the third erase state region ESR3 and a fourth program state P4 are used. These initial states are indicated by an ESR count value of 3. Assuming a ESR reference value of 4 a next programing operation will result in a physical erasing of the nonvolatile memory cell array prior to programming. Once the nonvolatile memory cell is physically erased and state information is reset, the process begins all over again.

FIG. 12 also illustrates the definition of incrementally increasing program verification voltages and read voltages that may be used in conjunction with a particular ESR count value for the nonvolatile memory cell. As will be appreciated from the foregoing description, the expanding erase state region and increasing program state require commensurate changes to the levels of relevant control voltages.

According to the foregoing embodiment physical erasure of the nonvolatile memory cell is only required after four successive programming operations. This programming approach greatly reduces nonvolatile memory cell fatigue, and extends the useful lifetime of the memory cells. It also allows the incorporating memory system to operate at increased speed, since numerous physical erase operations are omitted.

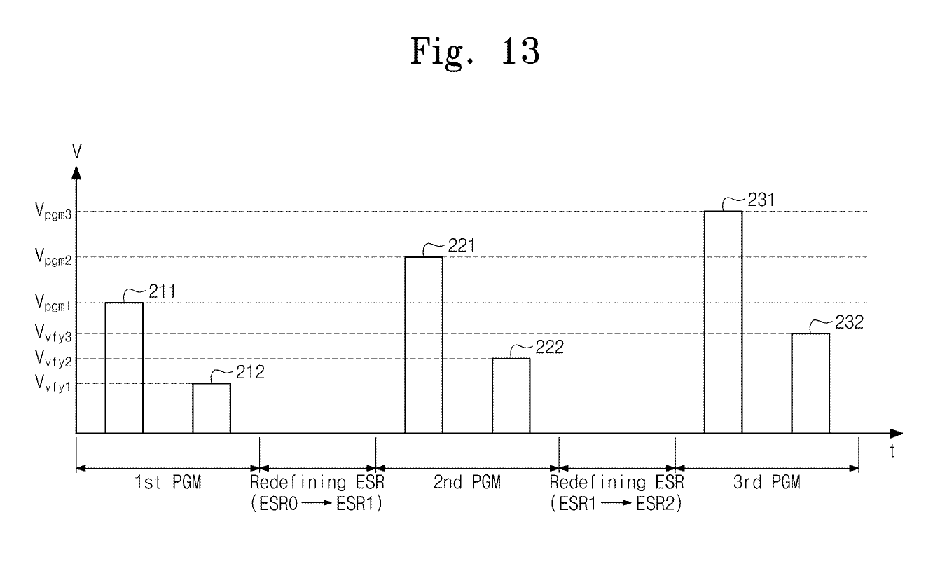

FIG. 13 is a voltage diagram illustrating various program voltages and verification voltages that may be used to program a nonvolatile memory cell according to certain embodiments of the inventive concept.

In FIG. 13, a first program voltage 211 and a first verification voltage 212 are voltages used during a first program operation. The nonvolatile memory device 100 may determine the levels of the first program voltage 211 and the first verification voltage 212 with reference to the (e.g.,) ESR count value.

After the first program operation, the erase state region of the memory cell is redefined to the first erase state region ESR1. Following erase state region redefinition, a second program operation is performed. During the second program, a second program voltage 221 and a second verification voltage 222 are used. The nonvolatile memory device 100 determines the levels of the second program voltage 221 and the second verification voltage 222 with reference (e.g.,) to the ESR count value.

During the second program operation, the erase state region is expanded over that used during the first program operation. Thus, the second program voltage 221 and the second verification voltage 222 will be respectively higher than the first program voltage 211 and the first verification voltage 212.

After the second program is complete, the erase state region is again redefined to the second erase state region ESR2. Following the erase state region redefinition, a third program operation is performed. During the third program, a third program voltage 231 and a third verification voltage 232 are used. Again, the nonvolatile memory device 100 may determine the levels of the third program voltage 231 and the third verification voltage 232 with reference to (e.g.,) the ESR count value.

During the third program operation, the erase state region for the memory cell is further expanded over the erase state region used during the second program operation. Thus, the third program voltage 231 and the third verification voltage 232 will be higher than the second program voltage 221 and the second verification voltage 222, respectively.

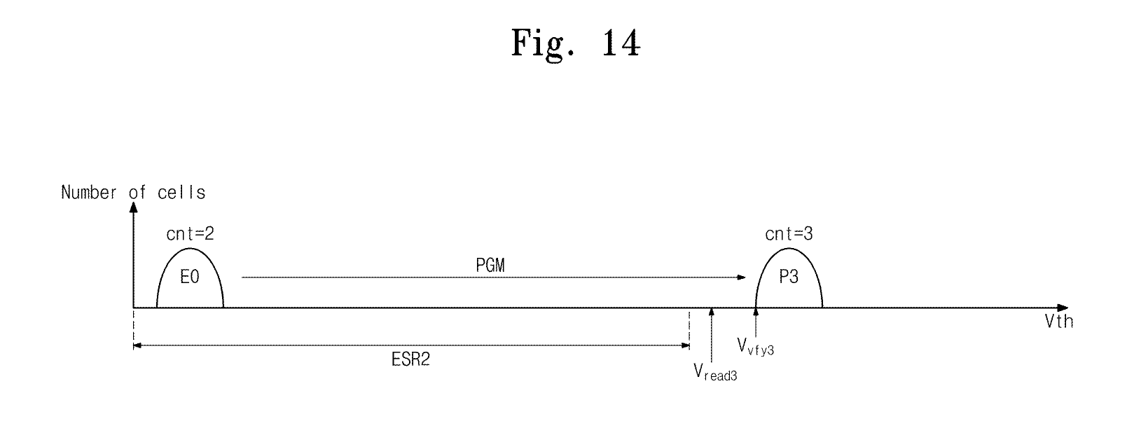

FIG. 14 is a conceptual diagram further illustrating an operating method for a nonvolatile memory device according to certain embodiments of the inventive concept. Referring to FIG. 14, it is assumed that a nonvolatile memory cell is capable of being accurately programmed from an initial erase state E0 to the third program state P3 during a single programming operation. Under such circumstances, it is not necessary to incrementally change the program state (P3) each time the erase state is incrementally changed as the result of am erase state redefinition. Rather, the threshold voltage distribution P3 is used in every instance to indicate the programmed state of the nonvolatile memory cell being operated as a SLC. Meanwhile, different (e.g., incrementally adjusted upward) erase state regions up to ESR2 may be used to indicate the erase state for the nonvolatile memory cell.

Further in such instances, the control logic 140 of the nonvolatile memory device 100 may determine an appropriate program voltage to be used in programming the nonvolatile memory cell by referencing to current erase state region for the memory cell. Thus, a relatively high program voltage is applied to the nonvolatile memory cell having the second erase state region ESR2 and thereby the memory cell can be programmed to the third program state P3 having a high threshold voltage in a single program operation.

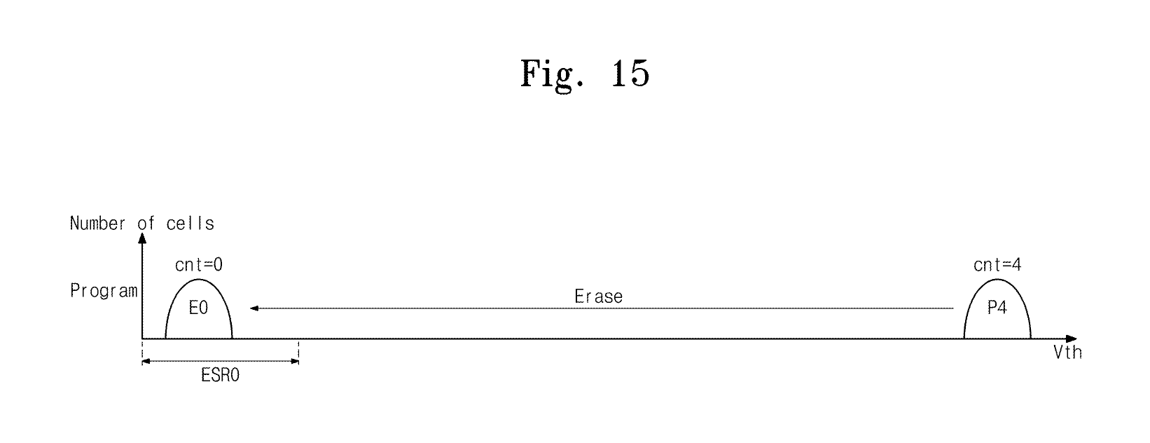

FIG. 15 is a conceptual diagram further illustrating a physical erase operation that may be performed on nonvolatile memory cells in accordance with certain embodiments of the inventive concept. Referring to FIG. 15, it is assumed that a ESR count value has reach 4—a maximum allowable ESR count value. Thus, in an immediately prior programming operation the nonvolatile memory cell was programmed in accordance with a fourth (and highest) program state P4.

In order to be again re-programmed under these conditions, the nonvolatile memory cell must first undergo a unique re-definition of sorts for its erase state region and program state region. Since no additional upward redefinition of the erase state region is possible, and/or no higher program state is possible, the nonvolatile memory cell must undergo a physical erasure (or reset redefinition). The physical erase operation, as noted above, may be a conventional erase operation applied to a nonvolatile memory cell or a defined group of nonvolatile memory cells. In effect, the erase state region is reset by redefinition to its initial erase state region ESR0. The program state may also be reset upon physical erasure of the nonvolatile memory cell.

The control logic 140 of the nonvolatile memory device 100 may be used to determine an erase voltage with reference to the erase state region of the nonvolatile memory cell. Thus, a relatively high erase voltage may be applied to the nonvolatile memory cell. For example, when the nonvolatile memory cell has been previously programmed to the fourth program state P4 having a high threshold voltage, the erase voltage required to reset the nonvolatile memory cell will be relatively high.

It is well understood that performing a physical erase operation by applying a high erase voltage increases the stress of the memory cell. Nonetheless, the reduced number of physical erase operations applied to a given nonvolatile memory cell by memory systems operating in accordance with the inventive concept markedly reduces the overall stress placed upon memory cells. Further, conventionally understood wear-leveling methods may be adapted and modified in view of the inventive concept to better distribute memory cell stress over the many constituent memory cells in the memory cell array 110.

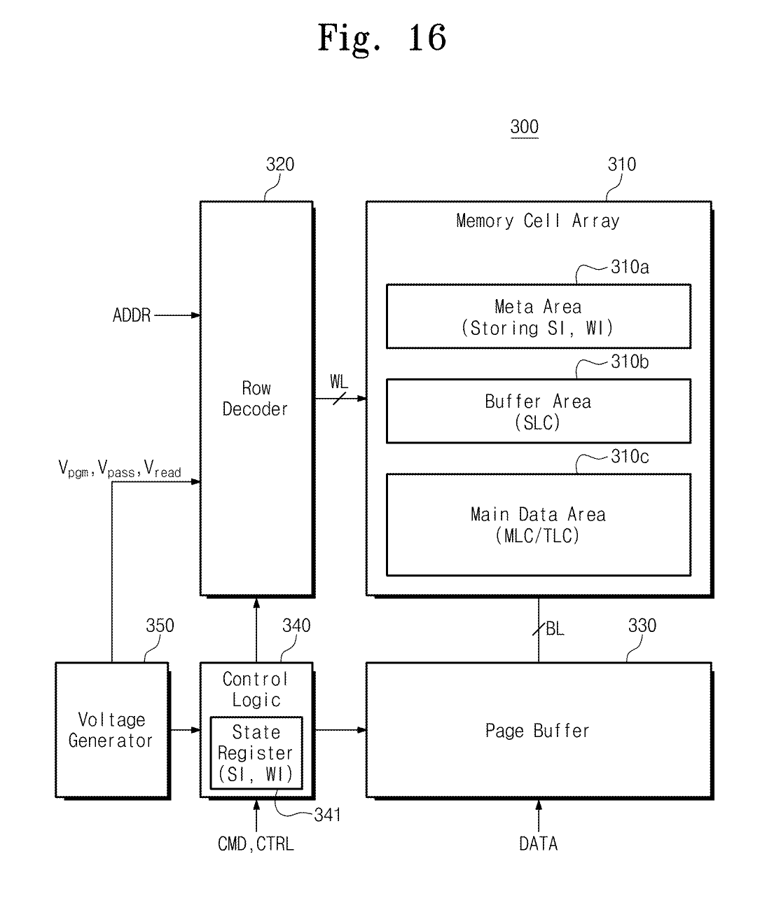

With this approach in mind, FIG. 16 is a block diagram illustrating a nonvolatile memory device in accordance with yet another embodiment of the inventive concept. Referring to FIG. 16, the nonvolatile memory device 300 analogously comprises a memory cell array 310, a row decoder 320, a page buffer 330, control logic 340 and a voltage generator 350. (Compare FIG. 2).

The meta area 310a may be used to store state information for the memory cells of the memory cell array 310. The state information may include information describing erase state information for respective memory cells. Hence, when the erase state and/or program state for a memory cell is redefined, the control logic 340 may reference and update the corresponding state information. The state information may also be stored in the register 341 included in the control logic 340. When performing a program or read operation on the memory cells of the memory cell array 310, the control logic 340 may determine an appropriate level for the requisite control voltages such as the program voltage, pass voltage, read voltage, or verification voltage by referencing the state information.

As before, the control logic 340 may be used to redefine the erase state region for any memory cell in the memory cell array 310 by updating the state information so that the state information corresponds to the redefined erase state region.

In addition to the foregoing, the nonvolatile memory device 300 may also store wearing information (WI) in the meta area 310a and/or the state register 341. In order to minimize the stress applied to any one memory cell (or defined group of memory cells e.g., a page), the control logic 340 may be used to manage the degree of wear experienced by memory cell on (e.g.,) a page unit basis by referencing to the wearing information (WI).

It is assumed that the memory cells of the memory cell array 310 are erased on a block unit basis. When an erase state region of any one memory page reaches a maximum value and therefor requires physical erasing, other memory pages included in the same block will also be erased regardless of their current ESR count value or erase state definition. Thus, without careful memory cell wear management, certain “overused” (i.e., frequently updated) pages included in a particular block might be result in relatively frequent physical erasure of the entire block. This is clearly undesirable since the over-frequent use of even a single page might result in the erase-stressing of all memory cells in the much larger block.

It has been seen that operating methods according to certain embodiments of the inventive concept are capable of reducing the number of physical erasures applied to individual memory cells or pages of memory cells. Nonetheless, intelligent wear management schemes should be applied to the memory cell array as a whole and to memory blocks as a whole to realize the maximum benefits of the inventive concept. For example, state redefinitions and programming operations are frequently performed on a specific page such that constituent memory cells are repeatedly programmed to a highest program state (e.g., P4) having a high threshold voltage, the specific memory page may suffer from an excessive stress.

Thus, according to the illustrated embodiment of FIG. 16, the control logic 310 may be used to manage the number of times each page is programmed, such that memory pages included in a particular block are respectively programmed with a relatively equal frequency to thereby minimize the need for physical erasure of any given page.

It is assumed by way of a simple example that there are first, second and third memory pages in a block. If the number of programming cycles applied to the first, second and third memory pages are 1, 3 and 10 respectively, the control logic 340 will thereafter refer to the wear information indicating this imbalance and preferentially program the first memory page which has the least number of applied programming cycles. Thus, the wear information for each memory page referenced by the control logic 340 may include a number of applied programming cycles, a number of applied physical erase cycles, erase state information, program state information, a current erase state count value, etc.

Within this configuration and using this a similar approaches, embodiments of the inventive concept, like the nonvolatile memory device 300 of FIG. 16, are able to effectively manage the degree of wearing for respective memory pages.

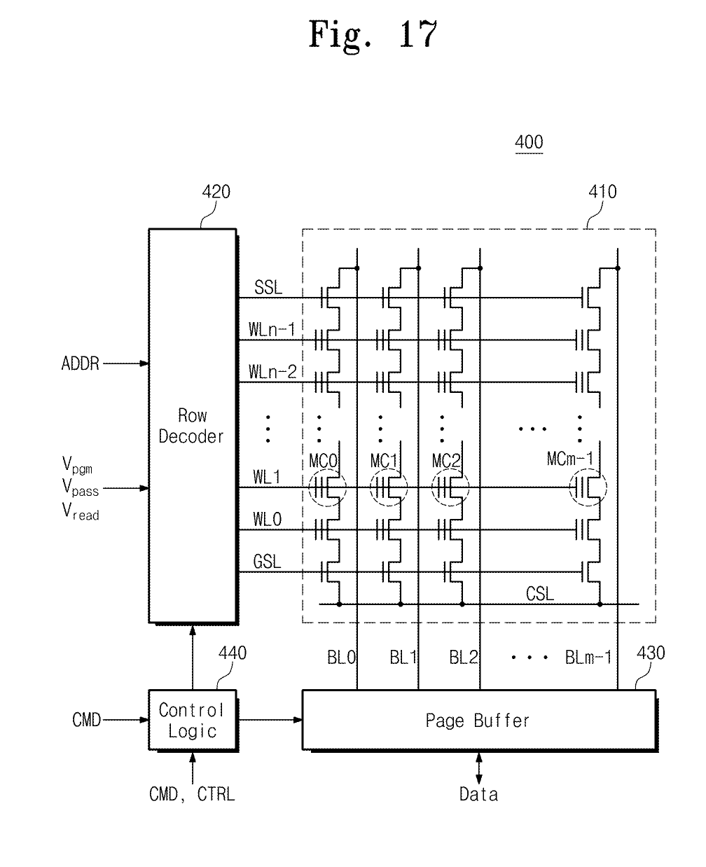

FIG. 17 is a block diagram further illustrating a nonvolatile memory device according to yet another embodiment of the inventive concept. Referring to FIG. 17, the nonvolatile memory device 400 generally comprises a memory cell array 410, a row decoder 420, a page buffer 430 and control logic 440.

Although not illustrated in FIG. 17, the nonvolatile memory device 400 may further include a voltage generator providing a pass voltage Vpass, a program voltage Vpgm, a verification voltage Vvfy and a read voltage Vread to the row decoder 420. The control logic 440 may include a state register storing state information of the memory cell array 410. The memory cell array 410 may include a meta area for storing state information.

The memory cell array 410 is connected to the row decoder 420 through word lines WLs or selection lines SSL and GSL. The memory cell array 410 is connected to the page buffer 430 through bit lines BL0˜BLm-1. The memory cell array 410 includes a plurality of NAND type cell strings. Each cell string is connected to a bit line through a string select transistor SST.

A plurality of memory cells connected to the same word line can be programmed in the same program cycle. Each of memory cells MC0˜MCm-1 connected to a word line WL1 may be programmed to the same program state or a different program state in the same program cycle. For example, in one program cycle, the memory cell MC0 may be programmed to a program state P1, the memory cell MC1 may be programmed to a program state P2 and the memory cells MC2 and MCm-1 may be programmed to a program state P3. The memory cell array 410 in accordance with some embodiments of the inventive concept may be formed with an all bit line (ABL) structure.

The row decoder 420 may select any one of memory blocks of the memory cell 410 in response to an address ADDR. The row decoder 420 may select any one of word lines of selected memory block. The row decoder 420 transfers a word line voltage from a voltage generator (not illustrated) to a word line of selected memory block. When a program operation is performed, the row decoder 420 transfers a program voltage Vpgm and a verification voltage Vvfy to a selected word line and transfers a pass voltage Vpass to an unselected word line.

The page buffer 430 operates as a write driver or a sense amplifier depending on an operation mode. When a program operation is performed, the page buffer 430 transfers a bit line voltage corresponding to data to be programmed to a bit lien of the memory cell array. When a read operation is performed, the page buffer 430 senses data stored in a selected memory cell through a bit line. The page buffer 430 latches the sensed data to enable output of the data state information to an external circuit.

The nonvolatile memory device 400 is also capable of managing an erase state region on a memory page basis (i.e., according to a set of memory cells connected to the same word line). Thus, even if a program state of each memory cell is different, the same program voltage, the same pass voltage and the same verification voltage are applied to a memory cell included in one memory page.

Similarly, memory cells included in one memory page are erased at the same time, and state information (or state count) and the erase state region are also initialized at the same time.

According to the above constitution, the erase state region for memory cells may be managed on a page unit basis. Thus, in the nonvolatile memory device 400, load managing the erase state region is reduced and memory space required to store state information is also reduced.

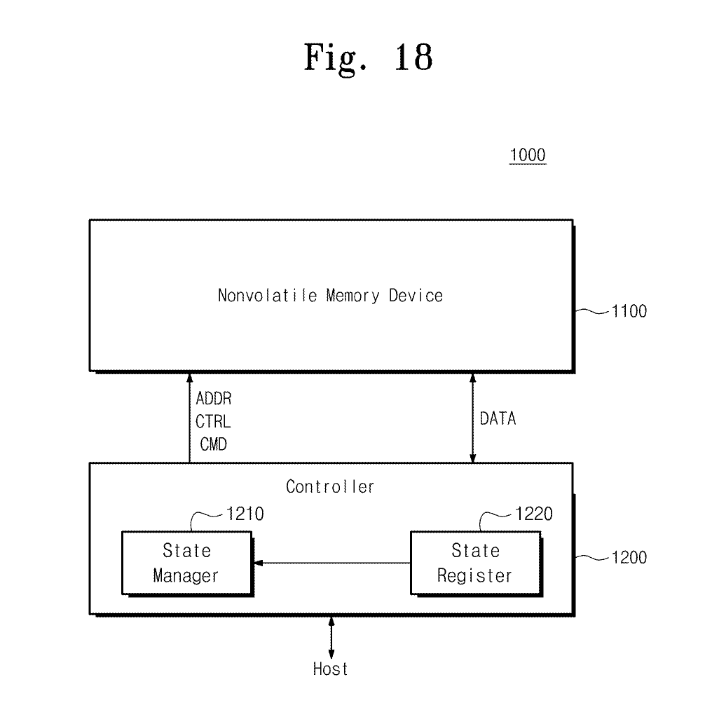

FIG. 18 is a block diagram illustrating a memory system in accordance with still another embodiment of the inventive concept. Referring to FIG. 18, the memory system 1000 generally comprises a nonvolatile memory device 1100 and a controller 1200.

The nonvolatile memory device 1100 may have the same structure as one of the nonvolatile memory devices 100 through 500 in accordance with some embodiments of the inventive concept. The nonvolatile memory device 1100 includes a plurality of cell strings CS11, CS12, CS21 and CS22 provided on a substrate 111. Each cell string includes a plurality of cell transistors CT stacked in a direction perpendicular to the substrate 111. The nonvolatile memory device 1100 may perform a program operation according to the program method described above. The nonvolatile memory device 1100 performs a state read and may consider a rearrangement according to a result of state read to perform a program operation.

The controller 1200 is connected to a host and the nonvolatile memory device 1100. In response to a request from the host, the controller 1200 is configured to access the nonvolatile memory device 1100. The controller 1200 is configured to control read, program, erase, redefinition of erase state region and wear-leveling operations of the nonvolatile memory device 1100. The controller 1200 is configured to provide an interface between the nonvolatile memory device 1100 and the host. The controller 1200 is configured to drive a firmware for controlling the nonvolatile memory device 1100.

The controller 1200 is configured to provide a control signal CTRL, a command CMD and an address ADDR to the nonvolatile memory device 1100. The controller 1200 provides a command CMD, a control signal CTRL and an address ADDR for program, erase and read operations to the nonvolatile memory device 1100 with reference to the erase state region of the nonvolatile memory device 1100.

In response to a command CMD, a control signal CTRL and an address ADDR being provided from the controller 1200, the nonvolatile memory device 1100 is configured to perform read, program, erase, redefinition of erase state region and wear-leveling operations.

The controller 1200 includes a state register 1220 storing state information for the nonvolatile memory device 1100 and a state manager 1210 generating and updating state information, and redefining the erase state region for the nonvolatile memory device 1100 with reference to the state information.

The nonvolatile memory device 1100 is capable of reading a plurality of memory pages included in a memory cell array (not illustrated) using a plurality of read voltages having different levels according to a command from the controller 1200. The nonvolatile memory device 1100 outputs a state read result according to the plurality of read voltages to the controller 1200. The state read result, among the plurality of read voltages, includes the read voltage of minimum level that makes all the memory cells of memory page being read become ON-cell.

The controller 1200 can find the erase state region of the nonvolatile memory device 1100 with reference to the state read result. If in the state read result, the read voltage of minimum level that makes all the memory cells of memory page which is read become ON-cell is a third voltage Vread3, an erase state region of the memory page includes a distribution of threshold voltage of erase state E0 and first and second program states P1 and P2. Thus, the erase state region of memory page being read may be determined to be the third erase state region ESR3.

On the basis of the identified erase state region, the controller 1200 may generate state information and store it in the state register 1220.

The controller 1200 may then update state information stored in the state register 1220 on the basis of the identified erase state region.

According to the embodiment of the inventive concept illustrated in FIG. 18, the memory system 1000 is able to accurately identify the current erase state region for a memory cell page even when corresponding state information is lost or unavailable.

The controller 1200 may further include constituent elements such as a processing unit, a host interface and a memory interface. The processing unit controls an overall operation of the controller 1200.

The host interface includes a protocol for performing a data exchange between the host and the controller 1200. The controller 1200 is configured to communicate with the outside through at least one of various interface protocols such as a universal serial bus (USB) protocol, a multimedia card (MMC) protocol, a peripheral component interconnection (PCI) protocol, a PCI-express protocol, an advanced technology attachment (ATA) protocol, a serial-ATA protocol, a parallel-ATA protocol, a small computer small interface (SCSI) protocol, an enhanced small disk interface (ESDI) protocol and an integrated drive electronic (IDE) protocol. The memory interface interfaces with the nonvolatile memory device 1100. The memory interface includes a NAND type interface or a NOR type interface.

The memory system 1000 is provided as one of various constituent elements of electronic device such as a computer, an ultra mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game machine, a navigation device, a black box, a digital camera, a digital multimedia broadcasting (DMB) player, a three dimensional television, a digital audio recorder, a digital audio player, a digital picture recorder, a digital picture player, a digital video recorder, a digital video player, a storage constituting a data center, a device that can transmit/receive information in a wireless environment, one of various electronic devices constituting a home network, one of various electronic devices constituting a computer network, one of various electronic devices constituting a telematics network, an RFID device, or one of various electronic devices constituting a computing system.

The nonvolatile memory device 1100 or the memory system 1000 can be mounted by various types of packages. For example, the nonvolatile memory device 1100 or the memory system 1000 can be mounted by various types of packages such as PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP) and wafer-level processed stack package (WSP).

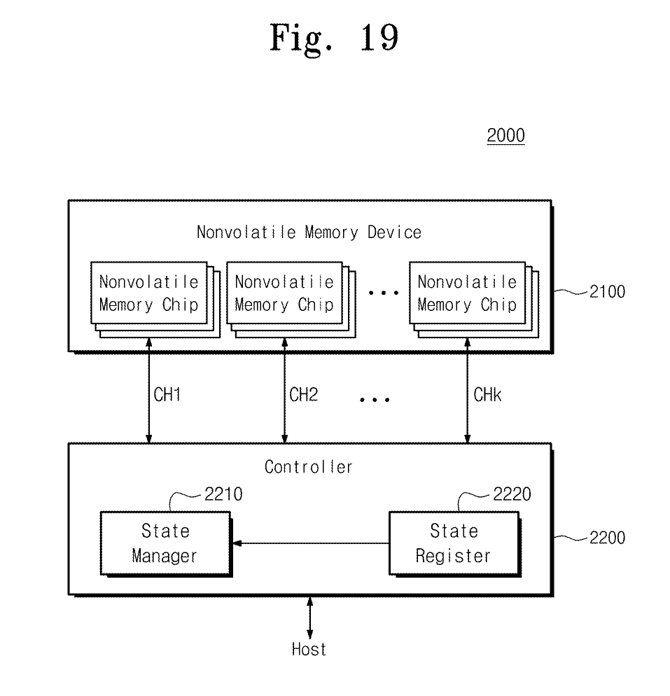

FIG. 19 is a block diagram illustrating a memory system in accordance with still another embodiment of the inventive concept. Referring to FIG. 19, the memory system 2000 includes a nonvolatile memory device 2100 and a controller 2200. The nonvolatile memory device 2100 includes a plurality of nonvolatile memory chips. The plurality of nonvolatile memory chips forms a plurality of groups. Each group of the plurality of nonvolatile memory chips is configured to communicate with the controller 2200 through one common channel. The plurality of nonvolatile memory chips can communicate with the controller 2200 through first through kth channels CH1˜CHk.

Each of the nonvolatile memory chips has the same structure as one of the nonvolatile memory devices 100 through 500 in accordance with some embodiments of the inventive concept and can operate in the same manner of one of the nonvolatile memory devices 100 through 500. The nonvolatile memory device 2100 includes a plurality of cell strings CS11, CS12, CS21 and CS22 provided on a substrate 111 and each cell string includes a plurality of cell transistors CT stacked in a direction perpendicular to the substrate 111.

In FIG. 19, a plurality of nonvolatile memory chips is connected to one channel. However, the memory system 2000 may be modified so that one nonvolatile memory chip is connected to one channel.

Except that the controller 2200 communicates with a plurality of nonvolatile memory chips through common channel, contents about the controller 2200 and nonvolatile memory device 2100 are the same as those described in FIG. 18.

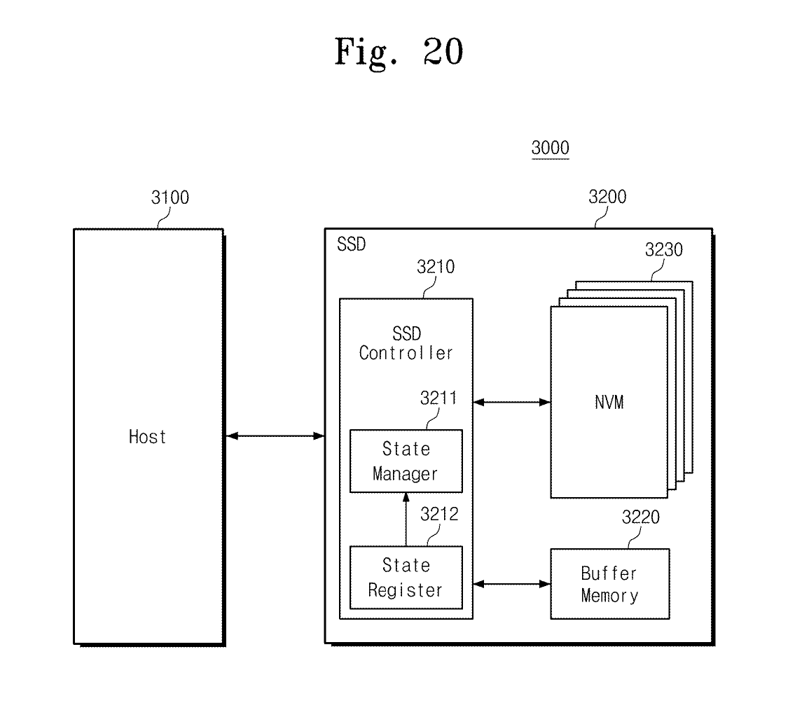

FIG. 20 is a block diagram illustrating a solid stage drive (SSD) in accordance yet another embodiment of the inventive concept. Referring to FIG. 20, a user device 3000 generally comprises a host 3100 and a SSD 3200. The SSD 3200 includes a SSD controller 3210, a buffer memory 3220 and a nonvolatile memory device 3230.

The SSD controller 3210 provides a physical connection between the host 3100 and the SSD 3200. The SSD controller 3210 provides an interfacing with the SSD 3200 in response to a bus format of the host 3100. The SSD controller 3210 decodes a command provided from the host 3100. According to a decoded result, the SSD controller 3210 accesses the nonvolatile memory device 3230.

The SSD controller 3210 is connected to the host 3100 and the nonvolatile memory device 3230. In response to a request from the host 3100, the SSD controller 3210 is configured to access the nonvolatile memory device 3230. The SSD controller 3210 is configured to control read, program, erase, redefinition of erase state region and wear-leveling operations of the nonvolatile memory device 3230. The SSD controller 3210 is configured to provide an interface between the nonvolatile memory device 3230 and the host 3100. The SSD controller 3210 is configured to drive a firmware for controlling the nonvolatile memory device 3230.

The SSD controller 3210 is configured to provide a control signal CTRL, a command CMD and an address ADDR to the nonvolatile memory device 3230. The SSD controller 3210 provides a command CMD, a control signal CTRL and an address ADDR for program, erase and read operations to the nonvolatile memory device 3230 with reference to the erase state region of the nonvolatile memory device 3230.

In response to a command CMD, a control signal CTRL and an address ADDR being provided from the controller 3210, the nonvolatile memory device 3230 is configured to perform read, program, erase, redefinition of erase state region and wear-leveling operations.

The controller 1200 includes a state register 3212 storing state information of the nonvolatile memory device 1100 and a state manager 3211 generating and renewing the state information and redefining the erase state region of the nonvolatile memory device 3230 with reference to the state information.

The nonvolatile memory device 3230 is able to read a plurality of memory pages included in a memory cell array (not illustrated) using a plurality of read voltages having different levels according to a command from the controller 3210. The nonvolatile memory device 3230 outputs a state read result according to the plurality of read voltages to the controller 3210. The state read result, among the plurality of read voltages, includes the read voltage of minimum level that makes all the memory cells of memory page being read become ON-cell.

The controller 3210 can find the erase state region of the nonvolatile memory device 3230 with reference to the state read result. If in the state read result, the read voltage of minimum level that makes all the memory cells of memory page being read become ON-cell is third voltage Vread3, an erase state region of the memory page includes a distribution of threshold voltage of erase state E0 and first and second program states P1 and P2. Thus, the erase state region for the memory cells of a memory page being read may be determined to be the third erase state region ESR3.

On the basis of the identified erase state region, the controller 3210 may generate state information and store it in the state register 3212. The controller 3210 may then update state information stored in the state register 3212 on the basis of the identified erase state region.

Examples of bus format of the host 3100 may be a universal serial bus (USB), a small computer system interface (SCSI), a PCI express, an ATA, a parallel ATA, a serial ATA, a serial attached SCSI, etc.

Write data provided from the host 3100 or data read from the nonvolatile memory device 3230 are temporarily stored in the buffer memory 3220. If data that exists in the nonvolatile memory device 3230 is cached when receiving a read request from the host 3100, the buffer memory 3220 support a cache function of directly providing the cached data to the host 3100. Generally, a data transmission speed by a bus format (e.g., SATA or SAS) of the host 3100 is much higher than a transmission speed of memory channel of the SSD 3200. When an interface speed of the host 3100 is much higher, performance degradation due to a difference of speed can be minimized by providing a large capacity buffer memory 3220.

The buffer memory 3220 may be provided as a synchronous DRAM to provide a sufficient buffering in the SSD 3200 used as an auxiliary mass storage device. However, the buffer memory 3220 may not be limited thereto.

The nonvolatile memory device 3230 is provided as a storage medium of the SSD 3200. The nonvolatile memory device 3230 may be provided as a NAND-type flash memory having high capacity storage ability. The nonvolatile memory device 3230 may be constituted by a plurality of memory devices. In this case, each memory device is connected to the SSD controller 3210 by a channel unit. As a storage medium, the nonvolatile memory device 3230 is described to be a NAND-type flash memory as an illustration, but the inventive concept is not limited thereto. For example, a PRAM, a MRAM, an ReRAM, a FRAM, a NOR flash memory, etc. may be used as a storage medium and a memory system in which different memory devices are mixed may be applied.

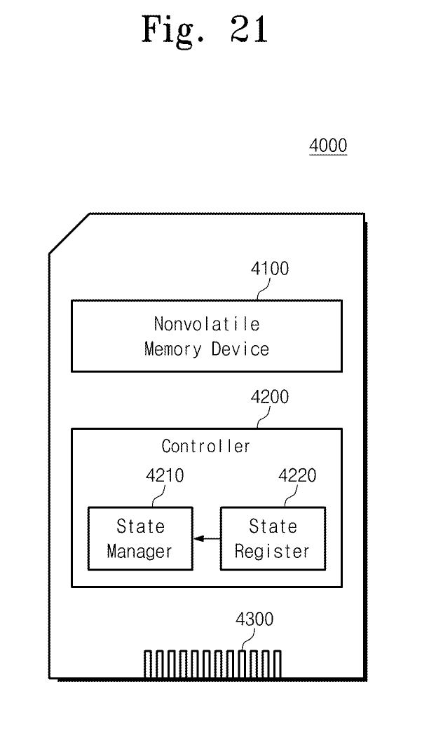

FIG. 21 is a block diagram illustrating a memory card 4000 in accordance with still another embodiment of the inventive concept. Referring to FIG. 21, the memory card 4000 comprises a nonvolatile memory device 4100, a controller 4200 and a connector 4300.

The nonvolatile memory device 4100 has the same structure as one of the nonvolatile memory devices 100 through 500 in accordance with some embodiments of the inventive concept and can operate in the same manner of one of the nonvolatile memory devices 100 through 500. The nonvolatile memory device 4100 includes a plurality of cell strings CS11, CS12, CS21 and CS22 provided on a substrate 111 and each cell string includes a plurality of cell transistors CT stacked in a direction perpendicular to the substrate 111.

The controller 4200 is connected to the nonvolatile memory device 4100. The controller 4200 is configured to access the nonvolatile memory device 4100. The controller 4200 is configured to control read, program, erase, redefinition of erase state region and wear-leveling operations of the nonvolatile memory device 4100. The controller 4200 is configured to provide an interface to the nonvolatile memory device 4100.

The controller 4200 is configured to provide a control signal CTRL, a command CMD and an address ADDR to the nonvolatile memory device 4100. The controller 4200 provides a command CMD, a control signal CTRL and an address ADDR for program, erase and read operations to the nonvolatile memory device 4100 with reference to the erase state region of the nonvolatile memory device 4100.

In response to a command CMD, a control signal CTRL and an address ADDR being provided from the controller 4200, the nonvolatile memory device 4100 is configured to perform read, program, erase, redefinition of erase state region and wear-leveling operations.

The controller 4200 includes a state register 4220 storing state information for the nonvolatile memory device 4100 and a state manager 4210 generating and updating the state information, and redefining the erase state region for the nonvolatile memory device 4100 with reference to the state information.

A detailed method by which the controller 4200 generates or updates the state information of the nonvolatile memory device 4100 may be the same as that described above.

The connector 4300 can electrically connect the memory card 4000 and a host.

The memory card 4000 can constitute memory cards such as a personal computer memory card international association (PCMCIA), a compact flash card (CF), a smart media card (SM, SMC), a memory stick, a multimedia card (MMC, RS-MMC, MMCmicro), a SD card (SD, miniSD, microSD, SDHC), a universal flash memory device (UFS), etc.

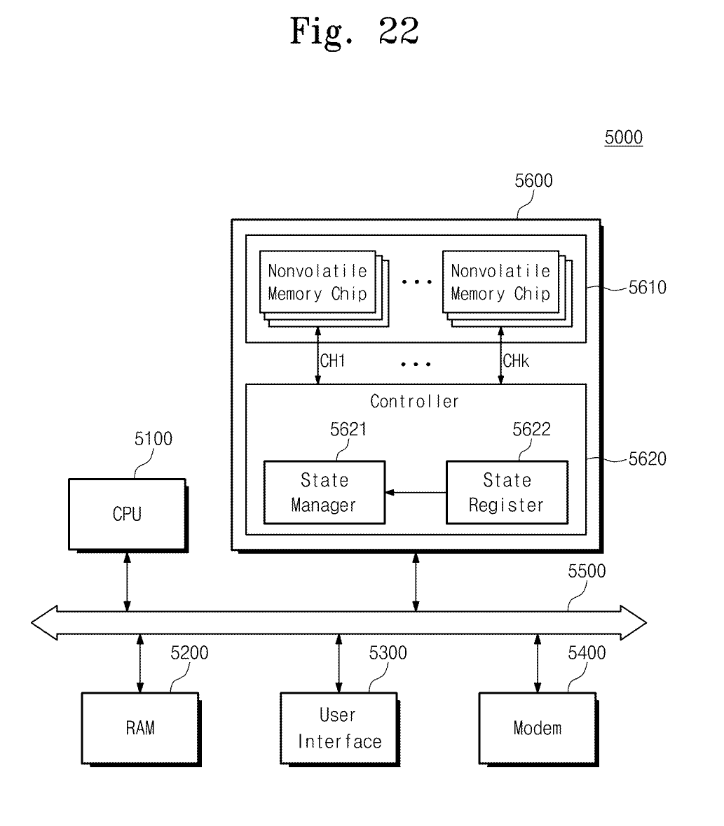

FIG. 22 is a block diagram illustrating a computational system in accordance with still another embodiment of the inventive concept. Referring to FIG. 22, a computational system 5000 comprises a central processing unit (CPU) 5100, a random access memory (RAM) 5200, a user interface 5300, a modem 5400 and a memory system 5600.

The memory system 5600 is electrically connected to the central processing unit (CPU) 5100, the random access memory (RAM) 5200, the user interface 5300 and the modem 5400 through a system bus 5500. Data provided through the user interface 5300 or processed by the CPU 5100 is stored in the memory system 5600.

The memory system 5600 includes a nonvolatile memory device 5610 and a controller 5620. The memory system 5600 may be the memory systems 1000 and 2000, the memory card 3000, or the solid state drive 4000 in accordance with certain embodiments of the inventive concept.

According to the inventive concept, as far as its fundamental characteristic permits, the erase state (and possibly the program state) for a nonvolatile memory cell may be redefined to enable successive programming operations instead of being physically erased prior to each programming. Therefore, the nonvolatile memory cell may successive re-programmed according to new state definitions without the necessity of performing a physical erase operation. Thus, physical erase frequency and the attendant memory cell stress may be reduced, thereby extending the useful life of the memory cell and increasing the operating speed of the nonvolatile memory device and nonvolatile memory system.

The foregoing is illustrative of the inventive concept and is not to be construed as limiting thereof. Although a few embodiments of the inventive concept have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. The inventive concept is defined by the following claims, with equivalents of the claims to be included therein

What is claimed is:

1. A programming method for a nonvolatile memory including a main area and a buffer area, the method comprising:
programming first data in a nonvolatile memory cell of the buffer area using a single-bit programming operation in accordance with one of an erase state and a program state;
invalidating the first data stored in the nonvolatile memory cell; and thereafter,
redefining the erase state.

2. The method of claim 1, wherein redefining the erase state comprises expanding a first erase threshold voltage distribution indicating the erase state to a second erase threshold voltage distribution indicating the redefined erase state.

3. The method of claim 2, wherein the second erase threshold voltage distribution subsumes the first erase threshold voltage distribution and a program threshold voltage distribution indicating the program state.

4. The method of claim 3, further comprising:
redefining the program state by changing a first program threshold voltage distribution indicating the program state to a second program threshold voltage distribution higher than the first program threshold voltage distribution and indicating the redefined program state.

5. The method of claim 4, further comprising:
after programming the first data in the nonvolatile memory cell, programming second data in the nonvolatile memory cell using a single-bit programming operation in accordance with one of the redefined erase state and the redefined program state before physically erasing the nonvolatile memory cell.

6. The method of claim 4, further comprising:
redefining a read voltage from a first level discriminating between the first erase threshold voltage distribution and the first program threshold voltage distribution to a second level discriminating between the second erase threshold voltage distribution and the second program threshold voltage distribution.

7. The method of claim 4, further comprising:
redefining a program voltage from a first level used to program the nonvolatile memory cell to the first program threshold voltage distribution during the single-bit programming operation to a second level used to program the nonvolatile memory cell to the second program threshold voltage distribution.

8. The method of claim 4, further comprising:
redefining a program verification voltage from a first level that discriminates between the first erase threshold voltage distribution and the first program threshold voltage distribution to a second level that discriminates between the second erase threshold voltage distribution and the second program threshold voltage distribution.

9. The method of claim 1, wherein the nonvolatile memory further includes a meta area that stores state information for the nonvolatile memory cell.

10. The method of claim 9, wherein redefining the erase state comprises updating the state information for the nonvolatile memory cell in the meta area.

11. The method of claim 1, wherein invalidating the first data stored in the nonvolatile memory cell occurs upon at least one of;
the first data is transferred to another nonvolatile memory cell in the main area,
the first data is copied to another nonvolatile memory cell,
the first data is merged from the nonvolatile memory cell to another nonvolatile memory cell in the buffer area, and
an error is detected in the first data.

12. The method of claim 1, wherein the main area and the buffer area are separately provided by different memory cell arrays of nonvolatile memory cells.

13. An operating method for a nonvolatile memory device, the method comprising:
programming first data in a nonvolatile memory cell using an Nth erase state among a group of 1^{st} through Mth erase states, and an Nth program state among a group of 1^{st} through Mth program states, where “N” is an integer ranging from 1 to M;
determining that an erase re-definition event has occurred for the nonvolatile memory cell;
redefining the Nth erase state to an (Nth+1) erase state;
redefining the Nth program state to an (Nth+1) program state; and
after programming the first data in the nonvolatile memory cell, programming second data in the nonvolatile memory cell in accordance with the (Nth+1) erase state and the (Nth+1) program state before physically erasing the nonvolatile memory cell.

14. The method of claim 13, wherein the redefining the Nth erase state to an (Nth+1) erase state and the redefining the Nth program state to an (Nth+1) program state is performed after determining that the erase re-definition event has occurred.

15. The method of claim 13, wherein the programming of the first data is performed in response to a first program command, and the programming of the second data is performed in response to a second program command received after the first program command, and
redefining the Nth erase state to the (Nth+1) erase state and redefining the Nth program state to an (Nth+1) program state is performed only after receiving the second program command.

16. The method of claim 13, wherein an (Nth+1) erase threshold voltage distribution indicating the (Nth+1) erase state is broader than an Nth erase threshold voltage distribution indicating the Nth erase state.

17. The method of claim 16, wherein the (Nth+1) erase threshold voltage distribution subsumes the Nth erase threshold voltage distribution and an Nth program threshold voltage distribution indicating the Nth program state.

18. An operating method for a nonvolatile memory device, comprising:
successively programming a nonvolatile memory cell without physically erasing the memory cell, wherein each successive programming of the memory cell uses a correspondingly expanded erase state region to indicate an erase state for the memory cell.

19. The method of claim 18, wherein each expanded erase state region subsumes a program state region indicating a program state for the memory cell during an immediately preceding programming of the memory cell.

20. The method of claim 19, further comprising:
physically erasing the memory cell only when an expanded erase state region reaches a maximum size.

21. The method of claim 19, further comprising:
for each successive programming of the memory cell, incrementing an erase state expansion count for the memory cell; and
determining whether the expanded erase state region reaches the maximum size by comparing the erase state expansion count with a reference value.

22. The method of claim 21, further comprising:
upon physically erasing the memory cell, resetting the erase state expansion count.

23. A nonvolatile memory, comprising:
a first memory including an array of nonvolatile memory cells; and
a second memory storing state information for the nonvolatile memory cells of the first memory, the state information defining a first erase state having a first erase state region, and a second erase state having a second erase state region different from the first erase state region.

24. The nonvolatile memory of claim 23, wherein the second memory is at least one of a state register in control logic for the nonvolatile memory, and a meta data area of the first memory.

25. The nonvolatile memory of claim 24, wherein the first memory comprises:
a buffer area of nonvolatile memory cells configured to store single bit data and further configured to temporarily store externally provided data; and
a main area of nonvolatile memory cells configured to store multi-bit data and further configured to receive and store data from the buffer area.

26. The nonvolatile memory of claim 23, wherein the array of nonvolatile memory cells is a three-dimensional (3D) memory cell array comprising:
a plurality of cells strings, each cell string extending in a first direction;
a plurality of word line extending in a second direction; and
a plurality of bit lines extending in a third direction.

27. The nonvolatile memory of claim 26, wherein the nonvolatile memory cells of each one of a plurality of physical pages are commonly controlled by one of the plurality of word lines, and are commonly disposed at a same height within the 3D memory cell array.

28. The nonvolatile memory of claim 26, wherein each cell string is connected to one of the plurality of bit lines and comprises a plurality of nonvolatile memory cells arranged in series between a string selection transistor (SST) and a ground selection transistor (GST), each one of the plurality of nonvolatile memory cells being respectively controlled by one of the plurality of word lines, each SST being controlled by a string selection line, and each GST being controlled by a ground selection line.

29. The nonvolatile memory of claim 26, wherein each of the nonvolatile memory cells is a charge trap flash (CTF) memory cell.

30. The nonvolatile memory of claim 25, wherein the first memory is a unitary memory cell array including portions designated to implement the meta area, buffer area and main area.

31. A nonvolatile memory, comprising:
control logic responsive to state information that controls successive execution of a first programming operation and a second programming operation;
a memory cell array of nonvolatile memory cells; and
a voltage generator operating under control of the control logic that during the first programming operation provides a first programming voltage to program a selected nonvolatile memory cell in accordance with a first erase state, and during the second programming operation provides a second programming voltage higher than the first programming voltage to program the selected nonvolatile memory cell in accordance with a second erase state different from the first erase state.

32. The nonvolatile memory of claim 31, wherein the state information defines a first erase state region for the first erase state and a second erase state region for the second erase state that is broader than and subsumes the first erase state region.

33. The nonvolatile memory of claim 31, wherein the voltage generator during the first programming operation provides a first verification voltage, and during the second programming operation provides a second verification voltage higher than the first verification voltage.

34. The nonvolatile memory of claim 31, wherein after execution of the first programming operation and before execution of the second programming operation, the voltage generator provides a first read voltage capable of distinguishing the first erase state from a first program state during a read operation, and
after execution of the second programming operation, the voltage generator provides a second read voltage higher than the first read voltage and capable of distinguishing the second erase state from a second program state higher than the first program state during the read operation.

35. The nonvolatile memory of claim 34, wherein the second erase state region subsumes a first program state region indicating the first program state.

36. The nonvolatile memory of claim 31, wherein the control logic comprises a state register storing the state information.

37. The nonvolatile memory of claim 31, wherein the nonvolatile memory cells are arranged according to a plurality of pages in a memory block, the memory block serving as a physical erase unit for the nonvolatile memory cells, and
the control logic is additionally responsive to wear information for the nonvolatile memory cells to control execution of programming operations to minimize a frequency of physical erase operations for the memory block.

38. A memory system, comprising:
a nonvolatile memory device and a controller configured to control operation of the nonvolatile memory device according to stored state information, wherein the state information defines for each nonvolatile memory cell of the nonvolatile memory device a first erase state having a first erase state region and a second erase state having a second erase state region broader than the first erase state region,
the controller being further configured to control execution of a first programming operation directed to a selected nonvolatile memory cell using the first erase state, and execution of a second programming operation directed to the nonvolatile memory cell using the second erase state,
the second programming operation being successively executed after the first programming operation before physical erasure of the selected nonvolatile memory cell.

39. The memory system of claim 38, wherein the nonvolatile memory device comprises a plurality of nonvolatile memory chips collectively arranged to communicate data with the controller via a plurality of channels.

40. The memory system of claim 38, wherein the controller comprises a state register storing the state information.

41. The memory system of claim 38, wherein the nonvolatile memory device and the controller are operatively arranged to implement a solid state drive (SSD).

42. The memory system of claim 38, wherein the nonvolatile memory device and the controller are operatively arranged to implement a memory card.
